(19) United States
(12) Patent Application Publication
(10) Pub. No.: US 2024/0038723 A1
(43) Pub. Date: Feb. 1, 2024

(54) CO-PACKAGE FOR QUBITS AND PARAMETRIC JOSEPHSON DEVICES

(71) Applicant: International Business Machines Corporation, Armonk, NY (US)

(72) Inventors: Jae-Woong Nah, Closter, NJ (US); David Abraham, Croton, NY (US); David Lokken-Toyli, White Plains, NY (US)

(21) Appl. No.: 17/815,457

(22) Filed: Jul. 27, 2022

(51) Int. Cl. H01L 25/065; H01L 23/00; H01L 39/04

(52) U.S. Cl. CPC H01L 25/0657; H01L 24/16; H01L 24/32; H01L 24/73; H01L 24/05; H01L 39/045; H01L 24/06; H01L 24/17; H01L 24/29; H01L 24/26; H01L 24/92; H01L 24/13; H01L 2225/06513; H01L 2224/16145; H01L 2224/32145; H01L 2224/73204; H01L 2224/2929; H01L 2924/0665; H01L 2224/29386; H01L 2924/05341; H01L 2924/05442; H01L 2224/29393; H01L 2924/01006; H01L 2224/0557; H01L 24/04; H01L 2224/0401; H01L 2224/05609; H01L 2224/05611; H01L 2224/05639; H01L 2224/05616; H01L 2924/0132; H01L 2224/16227; H01L 2224/06181; H01L 2224/17181; H01L 2224/26145; H01L 2224/29011; H01L 2224/92125; H01L 2224/13109; H01L 2224/13111; H01L 2224/13139; H01L 2224/13116

(57) ABSTRACT

Systems and techniques that facilitate high-density flip-chip co-packages for superconducting qubits and parametric Josephson devices are provided. In various embodiments, a device can comprise a superconducting qubit wafer that can be coupled, by one or more first bump-bonds, to a parametric Josephson wafer. In various aspects, the device can further comprise a first underfill that surrounds the one or more first bump-bonds. In various instances, the first underfill can protect the parametric Josephson wafer from mechanical and/or chemical degradation associated with subsequent fabrication, processing, and/or handling of the superconducting qubit wafer.

### BACKGROUND

The subject disclosure relates to qubits, and more specifically to high-density flip-chip co-packages for superconducting qubits and parametric Josephson devices.

Superconducting quantum computing hardware systems utilize parametric Josephson devices for signal boosting and/or noise mitigation purposes. Generally, such superconducting quantum computing hardware systems involve independently-packaged superconducting qubit chips that are coupled, by superconducting wires and/or coaxial cables, to separately-packaged parametric Josephson chips. Unfortunately, such separate packages take up excessive amounts of physical space and make it more difficult to facilitate cryogenic cooling and/or temperature control.

Accordingly, systems and/or techniques that can address one or more of these technical problems can be desirable.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, devices, systems, computer-implemented methods, apparatus, and/or computer program products that can facilitate high-density flip-chip co-packages for superconducting qubits and parametric Josephson devices are described.

According to one or more embodiments, a device is provided. In various aspects, the device can comprise a superconducting qubit wafer coupled, by one or more first bump-bonds, to a parametric Josephson wafer. In various instances, the device can further comprise a first underfill that surrounds the one or more first bump-bonds. In various cases, at least one first parametric Josephson device can be located on a first side of the parametric Josephson wafer, and at least one superconducting qubit comprising a Josephson junction can be located on a first side of the superconducting qubit wafer. In various aspects, the superconducting qubit wafer can include at least one first through-substrate via electrically connecting the first side of the superconducting qubit wafer to a second side of the superconducting qubit wafer. In various instances, the one or more first bump-bonds can couple the first side of the parametric Josephson wafer to the second side of the superconducting qubit wafer. In various cases, the first underfill can protect the at least one first parametric Josephson device from mechanical and/or chemical degradation associated with fabrication processing of the at least one superconducting qubit.

According to one or more embodiments, a flip-chip package is provided. In various aspects, the flip-chip package can comprise a first wafer bump-bonded to a second wafer. In various instances, the first wafer can include one or more parametric Josephson devices, and the second wafer can include one or more superconducting qubits. In various cases, the flip-chip package can further comprise an underfill that separates the first wafer from the second wafer. In various aspects, the underfill can protect/safeguard the one or more parametric Josephson devices from mechanical/chemical damage associated with fabrication, processing, and/or handling of the one or more superconducting qubits.

In various embodiments, the above-described device and/or flip-chip package can be implemented as methods of manufacture.

Various other details of various embodiments described herein are presented in the following clauses.

CLAUSE 1: A device, comprising: a superconducting qubit wafer coupled, by one or more first bump-bonds, to a parametric Josephson wafer; and a first underfill that surrounds the one or more first bump-bonds. As described herein, the first underfill can serve as a protective barrier that can help to prevent the parametric Josephson wafer from experiencing excessive mechanical and/or chemical degradation during subsequent fabrication and/or processing of the superconducting qubit wafer.

CLAUSE 2: The device of any preceding clause specified in the Summary, wherein the first underfill is a composite material comprising an epoxy polymer and a filler, wherein the filler is selected from the group consisting of silicon dioxide, titanium dioxide, carbon nanotubes, carbon black, and graphene.

CLAUSE 3: The device of any preceding clause specified in the Summary, wherein at least one first parametric Josephson device is located on a first side of the parametric Josephson wafer, wherein at least one superconducting qubit is located on a first side of the superconducting qubit wafer, wherein the superconducting qubit wafer includes at least one first through-substrate via electrically connecting the first side of the superconducting qubit wafer to a second side of the superconducting qubit wafer, and wherein the one or more first bump-bonds couple the first side of the parametric Josephson wafer to the second side of the superconducting qubit wafer. Again, as described herein, the first underfill can help to protect the at least one first parametric Josephson device from becoming mechanically damaged and/or chemically damaged during subsequent manufacturing and/or handling of the at least one superconducting qubit. Furthermore, as described herein, the first underfill can also help to mitigate cross-talk between adjacent ones of the at least one first parametric Josephson device.

CLAUSE 4: The device of any preceding clause specified in the Summary, wherein the at least one first parametric Josephson device includes a Josephson parametric amplifier, a Josephson travelling-wave parametric amplifier, a Josephson directional amplifier, a Josephson parametric converter, a Josephson circulator, or a Josephson isolator.

CLAUSE 5: The device of any preceding clause specified in the Summary, further comprising: an interposer wafer bump-bonded, by one or more second bump-bonds, to the superconducting qubit wafer, wherein at least one resonator is located on a first side of the interposer wafer.

CLAUSE 6: The device of any preceding clause specified in the Summary, wherein the one or more second bump-bonds couple the first side of the interposer wafer to the first side of the superconducting qubit wafer.

CLAUSE 7: The device of any preceding clause specified in the Summary, wherein the first side of the interposer wafer is bump-bonded to an organic substrate, and wherein the organic substrate is selected from the group consisting of a printed circuit board, a flexible printed circuit board, and a laminate.

CLAUSE 8: The device of any preceding clause specified in the Summary, further comprising: a first interposer wafer bump-bonded, by one or more second bump-bonds, to a second interposer wafer; and a second underfill that surrounds the one or more second bump-bonds.

CLAUSE 9: The device of any preceding clause specified in the Summary, wherein at least one second parametric Josephson device is located on a first side of the first interposer wafer, and wherein at least one resonator is located on a first side of the second interposer wafer.

CLAUSE 10: The device of any preceding clause specified in the Summary, wherein at least one second through-substrate via electrically connects the first side of the second interposer wafer to a second side of the second interposer wafer, and wherein the one or more second bump-bonds couple the first side of the first interposer wafer to the second side of the second interposer wafer.

CLAUSE 11: The device of any preceding clause specified in the Summary, wherein the first side of the superconducting qubit wafer is bump-bonded, by one or more third bump-bonds, to the first side of the second interposer wafer, wherein the first side of the second interposer wafer is bump-bonded to an organic substrate, and wherein the organic substrate is selected from the group consisting of a printed circuit board, a flexible printed circuit board, and a laminate. Again, as described herein, the second underfill can help to protect the at least one second parametric Josephson device from mechanical and/or chemical damage that might otherwise occur post-fabrication.

CLAUSE 12: The device of any preceding clause specified in the Summary, wherein at least one segmented electrode that corresponds to the at least one superconducting qubit is located on the second side of the superconducting qubit wafer, wherein the at least one segmented electrode includes at least one air bridge that is trimmable to tune an operational frequency of the at least one superconducting qubit, and wherein at least one hollow photoresist column stretches from the first side of the parametric Josephson wafer to the second side of the superconducting qubit wafer and prevents the underfill from covering the at least one air bridge.

CLAUSE 13: The device of any preceding clause specified in the Summary, further comprising: an interposer wafer; another superconducting qubit wafer coupled, by one or more second bump-bonds, to another parametric Josephson wafer; and a second underfill that surrounds the one or more second bump-bonds and that surrounds one or more second parametric Josephson devices of the another parametric Josephson wafer, wherein both the superconducting qubit wafer and the another superconducting qubit wafer are bump-bonded, by one or more third bump-bonds, to the interposer wafer, and wherein the interposer wafer is bump-bonded to an organic substrate.

In various embodiments, any combination and/or combinations of any of clauses 1-13 can be implemented.

CLAUSE 14: A method, comprising: coupling, by one or more first bump-bonds, a superconducting qubit wafer to a parametric Josephson wafer; and injecting a first underfill between the superconducting qubit wafer and the parametric Josephson wafer, such that the first underfill surrounds the one or more first bump-bonds. As described herein, the first underfill can serve as a protective barrier that can help to prevent the parametric Josephson wafer from experiencing excessive mechanical and/or chemical degradation during subsequent fabrication and/or processing of the superconducting qubit wafer.

CLAUSE 15: The method of any preceding clause specified in the Summary, wherein the first underfill is a composite material comprising an epoxy polymer and a filler, wherein the filler is selected from the group consisting of silicon dioxide, titanium dioxide, carbon nanotubes, carbon black, and graphene.

CLAUSE 16: The method of any preceding clause specified in the Summary, wherein at least one first parametric Josephson device is located on a first side of the parametric Josephson wafer, wherein at least one superconducting qubit is located on a first side of the superconducting qubit wafer, wherein the superconducting qubit wafer includes at least one first through-substrate via electrically connecting the first side of the superconducting qubit wafer to a second side of the superconducting qubit wafer, and wherein the one or more first bump-bonds couple the first side of the parametric Josephson wafer to the second side of the superconducting qubit wafer. Again, as described herein, the first underfill can help to protect the at least one first parametric Josephson device from becoming mechanically damaged and/or chemically damaged during subsequent manufacturing and/or handling of the at least one superconducting qubit. Furthermore, as described herein, the first underfill can also help to mitigate cross-talk between adjacent ones of the at least one first parametric Josephson device.

CLAUSE 17: The method of any preceding clause specified in the Summary, wherein the at least one first parametric Josephson device includes a Josephson parametric amplifier, a Josephson travelling-wave parametric amplifier, a Josephson directional amplifier, a Josephson parametric converter, a Josephson circulator, or a Josephson isolator.

CLAUSE 18: The method of any preceding clause specified in the Summary, further comprising: coupling, by one or more second bump-bonds, an interposer wafer to the superconducting qubit wafer, wherein at least one resonator is located on a first side of the interposer wafer.

CLAUSE 19: The method of any preceding clause specified in the Summary, wherein the one or more second bump-bonds couple the first side of the interposer wafer to the first side of the superconducting qubit wafer.

CLAUSE 20: The method of any preceding clause specified in the Summary, wherein the first side of the interposer wafer is bump-bonded to an organic substrate, and wherein the organic substrate is selected from the group consisting of a printed circuit board, a flexible printed circuit board, and a laminate.

CLAUSE 21: The method of any preceding clause specified in the Summary, further comprising: coupling, by one or more second bump-bonds, a first interposer wafer to a second interposer wafer; and injecting a second underfill between the first interposer wafer and the second interposer wafer, such that the second underfill surrounds the one or more second bump-bonds.

CLAUSE 22: The method of any preceding clause specified in the Summary, wherein at least one second parametric Josephson device is located on a first side of the first interposer wafer, and wherein at least one resonator is located on a first side of the second interposer wafer.

CLAUSE 23: The method of any preceding clause specified in the Summary, wherein at least one second through-substrate via electrically connects the first side of the second interposer wafer to a second side of the second interposer wafer, and wherein the one or more second bump-bonds couple the first side of the first interposer wafer to the second side of the second interposer wafer.

CLAUSE 24: The method of any preceding clause specified in the Summary, wherein the first side of the superconducting qubit wafer is bump-bonded, by one or more third bump-bonds, to the first side of the second interposer wafer, wherein the first side of the second interposer wafer is bump-bonded to an organic substrate, and wherein the organic substrate is selected from the group consisting of a printed circuit board, a flexible printed circuit board, and a laminate. Again, as described herein, the second underfill can help to protect the at least one second parametric Josephson device from mechanical and/or chemical damage that might otherwise occur post-fabrication.

CLAUSE 25: The method of any preceding clause specified in the Summary, wherein at least one segmented electrode that corresponds to the at least one superconducting qubit is located on the second side of the superconducting qubit wafer, wherein the at least one segmented electrode includes at least one air bridge that is trimmable to tune an operational frequency of the at least one superconducting qubit, and wherein at least one hollow photoresist column stretches from the first side of the parametric Josephson wafer to the second side of the superconducting qubit wafer and prevents the first underfill from covering the at least one air bridge.

CLAUSE 26: The method of any preceding clause specified in the Summary, further comprising: coupling, by one or more second bump-bonds, another superconducting qubit wafer to another parametric Josephson wafer; injecting a second underfill between the another superconducting qubit wafer and the another parametric Josephson wafer, such that the second underfill surrounds the one or more second bump-bonds and surrounds one or more second parametric Josephson devices of the another parametric Josephson wafer; and coupling, by one or more third bump-bonds, both the superconducting qubit wafer and the another superconducting qubit wafer to an interposer wafer, wherein the interposer wafer is bump-bonded to an organic substrate.

In various embodiments, any combination and/or combinations of any of clauses 14-26 can be implemented.

CLAUSE 27: A flip-chip package, comprising: a first wafer bump-bonded to a second wafer, wherein the first wafer includes one or more parametric Josephson devices, and wherein the second wafer includes one or more superconducting qubits; and an underfill that separates the first wafer from the second wafer, wherein the one or more parametric Josephson devices are located between the underfill and the first wafer. As described herein, the underfill can serve as a protective barrier that can help to prevent the one or more parametric Josephson devices from experiencing excessive mechanical and/or chemical degradation during subsequent fabrication and/or processing of the one or more superconducting qubits.

CLAUSE 28: The flip-chip package of any preceding clause specified in the Summary, further comprising: an interposer that is bump-bonded to both the second wafer and an organic substrate.

CLAUSE 29: The flip-chip package of any preceding clause specified in the Summary, wherein the interposer includes one or more resonators.

CLAUSE 30: The flip-chip package of any preceding clause specified in the Summary, wherein the interposer includes a first interposer wafer bump-bonded to a second interposer wafer, wherein the first interposer wafer includes one or more other parametric Josephson devices, wherein the second interposer wafer includes one or more resonators, wherein another underfill separates the first interposer wafer from the second interposer wafer, wherein the second wafer is bump-bonded to the second interposer wafer, and wherein the another underfill is configured to protect the one or more other parametric Josephson devices from mechanical or chemical damage.

In various embodiments, any combination and/or combinations of any of clauses 27-30 can be implemented.

### DESCRIPTION OF THE DRAWINGS

FIG. 1 illustrates a cross-sectional diagram of an example, non-limiting high-density flip-chip co-package for superconducting qubits and parametric Josephson devices in accordance with one or more embodiments described herein.

FIGS. 2-13 illustrate example, non-limiting cross-sectional diagrams showing how a high-density flip-chip co-package for superconducting qubits and parametric Josephson devices can be fabricated in accordance with one or more embodiments described herein.

FIGS. 14-16 illustrate example, non-limiting block diagrams explaining how a high-density flip-chip co-package for superconducting qubits and parametric Josephson devices can be fabricated in accordance with one or more embodiments described herein.

FIGS. 17-18 illustrate example, non-limiting cross-sectional diagrams showing how a high-density flip-chip co-package for superconducting qubits and parametric Josephson devices can be coupled to an interposer and/or an organic substrate in accordance with one or more embodiments described herein.

FIGS. 19-20 illustrate example, non-limiting cross-sectional diagrams showing how a high-density flip-chip co-package for superconducting qubits and parametric Josephson devices can be coupled to an alternative interposer and/or an organic substrate in accordance with one or more embodiments described herein.

FIG. 21 illustrates a cross-sectional diagram of an example, non-limiting high-density flip-chip co-package for superconducting qubits and parametric Josephson devices including a trimmable air bridge for frequency tuning in accordance with one or more embodiments described herein.

FIGS. 22-23 illustrate example, non-limiting cross-sectional diagrams showing how a high-density flip-chip co-package for superconducting qubits and parametric Josephson devices including a trimmable air bridge for frequency tuning can be coupled to interposers and/or organic substrates in accordance with one or more embodiments described herein.

FIGS. 24-25 illustrate cross-sectional diagrams of another example, non-limiting high-density flip-chip co-package for superconducting qubits and parametric Josephson devices coupled to interposers and/or organic substrates in accordance with one or more embodiments described herein.

FIG. 26 illustrates a block diagram of an example, non-limiting method for facilitating high-density flip-chip co-packages for superconducting qubits and parametric Josephson devices in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Superconducting quantum computing hardware systems (e.g., quantum computers that utilize superconducting qubits made up of Josephson junctions, such as transmon qubits) can utilize parametric Josephson devices for signal boosting and/or noise mitigation purposes. In various cases, a parametric device can be any suitable electronic circuit that utilizes a time-varying parameter to couple multiple modes of operation. In various instances, a parametric Josephson device can be a parametric device whose time-varying parameter is Josephson inductance. Non-limiting examples of parametric Josephson devices can include Josephson travelling-wave parametric amplifiers, Josephson parametric amplifiers, Josephson directional amplifiers, Josephson parametric converters, Josephson circulators, Josephson isolators, traveling-wave frequency converters, and/or traveling-wave frequency isolators. In any case, as superconducting quantum computing hardware systems are scaled-up, they can be expected to contain up to millions of qubits and to require near-perfect yield of all cryogenic components on assembly. Since parametric Josephson devices often multiplex signals from multiple qubits, failures of such parametric Josephson devices can be particularly problematic.

Generally, superconducting quantum computing hardware systems can involve independently-packaged superconducting qubit chips (e.g., silicon chips on which one or more superconducting qubits are fabricated) that are coupled, by superconducting wires and/or coaxial cables, to separately-packaged parametric Josephson chips (e.g., silicon chips on which one or more parametric Josephson devices are fabricated). Such separate packaging is implemented to allow for the parametric Josephson chips and/or for the superconducting qubit chips to be separately removed/serviced in large-scale quantum computing systems.

Unfortunately, although such separate packaging helps to ease servicing/repair of individual components, such separate packaging takes up excessive amounts of physical space and makes it more difficult to facilitate cryogenic cooling. More specifically, a significant amount of physical volume within a cryogenic refrigerator can be taken up not only by the superconducting qubit chips and the separately-packaged parametric Josephson chips themselves, but also by mounting brackets, magnetic shields, and/or cooling apparatuses required by the superconducting qubit chips, further by separate/duplicative mounting brackets, separate/duplicative magnetic shields, and/or separate/duplicative cooling apparatuses required by the separately-packaged parametric Josephson chips, and further still by the lengthy superconducting wires and/or coaxial cables needed to couple the superconducting qubit chips to the separately-packaged parametric Josephson chips. Accordingly, as superconducting quantum computing hardware systems scale to hundreds, thousands, or even millions of qubits, separately packaging superconducting qubit chips and parametric Josephson chips can necessitate larger and larger cryogenic refrigerators, which can quickly become impractical. In other words, separately packaging the superconducting qubit chips and the parametric Josephson chips can be disadvantageous due to overconsumption of physical space and/or due to the concomitant cooling challenges caused by such overconsumption of physical space.

One potential solution to such overconsumption of physical space is the implementation of flip-chip packaging with respect to superconducting qubit chips and parametric Josephson chips. That is, space can be saved by bonding, in flip-chip fashion, a superconducting qubit chip to a parametric Josephson chip, since separate/duplicative mounting brackets, separate/duplicative magnetic shields, and/or separate/duplicative cooling apparatuses can then be omitted. Unfortunately, however, existing techniques for implementing such flip-chip packaging often cause significant mechanical and/or chemical degradation of the parametric Josephson devices to occur, which can be undesirable.

Accordingly, systems and/or techniques that can address one or more of these technical problems can be desirable.

Various embodiments described herein can address one or more of these technical problems. Specifically, various embodiments described herein can provide systems and/or techniques that can facilitate high-density flip-chip co-packages for superconducting qubits and parametric Josephson devices. In other words, the present inventors of various embodiments described herein devised a unified packaging architecture that can implement both superconducting qubits and parametric Josephson devices, thereby eliminating the overconsumption of physical space that characterizes separate-packaging techniques, while at the same time avoiding the mechanical and/or chemical degradation of parametric Josephson devices that plagues existing flip-chip packaging techniques. That is, the present inventors devised a technique for fabricating both superconducting qubits and parametric Josephson devices together into a single flip-chip package, where such single flip-chip package can exhibit higher spatial density (e.g., can be geometrically more compact) as compared to a situation in which the superconducting qubits and the parametric Josephson devices are separately-packaged, and where the parametric Josephson devices of such single flip-chip package can exhibit no (and/or at most negligible) mechanical and/or chemical degradation.

In particular, the architecture devised by the present inventors can, in various aspects, include a superconducting qubit wafer and a parametric Josephson wafer. In various instances, the superconducting qubit wafer can be comprised of any suitable quantum computing wafer/substrate material (e.g., silicon) and/or can have any suitable shape, size, and/or dimensions as desired. In various cases, the superconducting qubit wafer can be considered as having a first side (e.g., a top-side) and a second side (e.g., a bottom-side). In various aspects, the first side of the superconducting qubit wafer and the second side of the superconducting qubit wafer can be electrically connected together by one or more through-substrate vias being comprised of any suitable superconducting materials. In various instances, one or more superconducting qubits (e.g., transmon qubits) can be fabricated (e.g., via photolithography, deposition, etching, and/or double-angle evaporation) on the first side of the superconducting qubit wafer.

In various aspects, the parametric Josephson wafer can be comprised of any suitable quantum computing wafer/substrate material (e.g., silicon) and/or can have any suitable shape, size, and/or dimensions as desired. In various instances, just as above, the parametric Josephson wafer can be considered as having a first side (e.g., a top-side) and a second side (e.g., a bottom-side). In various cases, one or more parametric Josephson devices (e.g., Josephson travelling-wave parametric amplifiers, Josephson parametric amplifiers, Josephson directional amplifiers, Josephson parametric converters, Josephson circulators, Josephson isolators, traveling-wave frequency converters, traveling-wave frequency isolators) can be fabricated (e.g., via photolithography, deposition, etching, and/or double-angle evaporation) on the first side of the parametric Josephson wafer.

In various aspects, the second side of the superconducting qubit wafer and the first side of the parametric Josephson wafer can be coupled (e.g., through reflow bonding, thermal compression bonding, cold welding) by one or more bump-bonds (e.g., which can be fabricated via photolithography, deposition, etching, double-angle evaporation, injection molding, and/or electroplating). In various cases, each bump-bond can comprise a solder bump sandwiched between two under-bump metallizations. Accordingly, the superconducting qubit wafer and the parametric Josephson wafer can be considered as being coupled together in a single and/or spatially-compact flip-chip package. Such single, compact flip-chip package can consume less geometric volume than the above-described technique of fabricating superconducting qubits and parametric Josephson devices in separate packages (e.g., when parametric Josephson devices are packaged separately from superconducting qubits, separate/duplicative mounting brackets, separate/duplicative magnetic shields, and/or separate/duplicative cooling apparatuses can be required; in contrast, when parametric Josephson devices are packaged together with superconducting qubits in the herein-described single, compact flip-chip package, separate/duplicative mounting brackets, separate/duplicative magnetic shields, and/or separate/duplicative cooling apparatuses can be eschewed).

Furthermore, although the first side of the parametric Josephson wafer and the second side of the superconducting qubit wafer can be coupled by the one or more bump-bonds, there can nevertheless be interstitial spatial gaps that surround the one or more bump-bonds, that surround the one or more parametric Josephson devices, and/or that separate the first side of the parametric Josephson wafer from the second side of the superconducting qubit wafer. In various cases, an underfill can be injected into such interstitial spatial gaps, such that the underfill surrounds the one or more bump-bonds, surrounds/covers the one or more parametric Josephson devices, and/or separates the first side of the parametric Josephson wafer from the second side of the superconducting qubit wafer. In various aspects, the underfill can be any suitable type of thermoset epoxy. As a non-limiting example, the underfill can be a composite material that includes any suitable epoxy polymer in combination with any suitable filler. Non-limiting examples of such filler can be silicon dioxide, titanium dioxide, carbon nanotubes, carbon black, and/or graphene. In various cases, the underfill can include any other suitable materials, such as flow agents, adhesion promoters, and/or dyes. In various instances, the composition of the underfill can be controlled so as to ensure that the underfill is coefficient-of-thermal-expansion-matched (e.g., CTE-matched) with the superconducting qubit wafer and/or the parametric Josephson wafer (e.g., since the superconducting qubit wafer and the parametric Josephson wafer can both be silicon, they can have a same coefficient-of-thermal-expansion). Furthermore, in various aspects, any suitable curing process (e.g., any suitable curing temperature and/or curing time) can be implemented after injection of the underfill.

In any case, the present inventors realized that the underfill can act as an intermediate physical barrier that can protect the parametric Josephson devices from mechanical stresses and/or chemical degradation that would otherwise occur during subsequent fabrication/processing. More specifically, given the practical realities of modern microfabrication and/or nanofabrication equipment, the order in which the various components of the herein-described single, compact flip-chip package can be manufactured can be as follows: the parametric Josephson devices can be manufactured on a first side of a first substrate, thereby yielding the parametric Josephson wafer; a second side of a second substrate, which second substrate can have through-substrate vias but can lack superconducting qubits, can be bumped-bonded in flip-chip fashion to the first side of the parametric Josephson wafer; the underfill can be injected between the first side of the parametric Josephson wafer and the second side of the second substrate, such that the underfill surrounds/covers the bump-bonds and/or the parametric Josephson devices; and superconducting qubits can subsequently be manufactured on the first side of the second substrate, thereby yielding the superconducting qubit wafer. With such relative order of fabrication, the underfill can be considered as physically safeguarding and/or physically reinforcing the parametric Josephson devices during the subsequent fabrication of the superconducting qubits. In other words, if the underfill were omitted, then the subsequent fabrication (e.g., via photolithography, deposition, etching, double-angle evaporation) of the superconducting qubits on the first side of the second substrate would subject the already-fabricated parametric Josephson devices to high levels of mechanical stresses (which can lead to physical fracturing of the parametric Josephson devices) and/or would subject the already-fabricated parametric Josephson devices to high levels of chemical corrosion (which can adversely affect the signal-boosting and/or noise-mitigation performance of the parametric Josephson devices). In contrast, when the underfill is included as described herein, the mechanical stresses and/or chemical corrosion of the parametric Josephson devices that would otherwise arise during the subsequent fabrication of the superconducting qubits can be mitigated and/or reduced to negligible levels. Thus, the underfill can be considered as an intermediate physical barrier that safeguards the parametric Josephson devices from mechanical and/or chemical damage that would otherwise occur during subsequent fabrication/processing undergone by the single, compact flip-chip package described herein.

Relatedly, the underfill can further be considered as protecting the parametric Josephson devices and/or the bump bonds from mechanical damage that might otherwise occur during post-fabrication handling of the single, compact flip-chip package described herein. For example, post-fabrication handling of the single, compact flip-chip package described herein can present many different opportunities for physical damage to occur (e.g., placing the single, compact flip-chip package into various clamps and/or mounts can cause transient and/or non-transient mechanical stresses to accrue within/around the parametric Josephson devices and/or within/around the bump bonds). In various cases, the underfill can be considered as increasing the physical durability of the parametric Josephson devices and/or of the bump bonds, so that the parametric Josephson devices and/or the bump bonds can be more likely to survive such mechanical stresses that can occur during post-fabrication handling without sustaining damage.

In various aspects, the present inventors realized that a further benefit of the underfill can be reduction of crosstalk between adjacent parametric Josephson devices. In particular, a material with comparatively high radiofrequency absorption, such as carbon nanotubes, can be used as a primary filler/constituent of the underfill. In such case, the underfill can thus serve to attenuate free-space electromagnetic fields (e.g., crosstalk) that might occur between adjacent ones of the parametric Josephson devices.

Note that, prior to the ingenuity of the present inventors and/or prior to the teachings explained in the herein disclosure, underfill had been used only to correct for coefficient-of-thermal-expansion mismatches between silicon wafers and non-silicon organic substrates (e.g., printed-circuit boards, laminates). In other words, prior to the herein-described teachings, underfill had generally been used between a silicon wafer and an organic substrate (e.g., since silicon wafers and organic substrates can have different coefficients-of-thermal-expansion), but underfill had not generally been used between two silicon wafers (e.g., since silicon wafers can already have the same coefficient-of-thermal-expansion as each other). Furthermore, prior to the herein-described teachings, underfill had not been used in any way as a physical barrier to protect parametric Josephson devices from mechanical and/or chemical damage caused by subsequent fabrication/processing of superconducting qubits. Indeed, prior to the herein-described teachings, there existed no indication whatsoever that underfill could even serve as a suitable barrier for providing such mechanical/chemical protection. In fact, the very concept of a shield/barrier to protect parametric Josephson devices from mechanical/chemical damage caused by subsequent fabrication of superconducting qubits did not exist prior to the herein-described teachings. Instead, as explained above, such mechanical/chemical damage was avoided by existing techniques through separately-packaging the superconducting qubits and the parametric Josephson devices, at the cost of excessive consumption of space.

In any case, the single, compact flip-chip package described herein can implement superconducting qubits and parametric Josephson devices with no and/or negligible mechanical/chemical damage (e.g., due to the underfill) in a high-density (e.g., in a geometrically compact) fashion. Accordingly, such single, compact flip-chip package can be considered as advantageous as compared to techniques that involve separately-packaging superconducting qubits and parametric Josephson devices (e.g., although such separate-packaging techniques can avoid undesirable mechanical/chemical damage of the parametric Josephson devices, such separate-packaging techniques consume excessive amounts of physical space).

Various embodiments of the invention can be employed to use hardware and/or software to solve problems that are highly technical in nature (e.g., to facilitate high-density flip-chip co-packages for superconducting qubits and parametric Josephson devices), that are not abstract, that are not mere laws of nature, that are not mere natural phenomena, and that cannot be performed as a set of mental acts by a human. Instead, various embodiments described herein include tangible electric circuit structures/architectures and/or methodologies pertaining to such tangible electric circuit structures/architectures that can be utilized so as to implement superconducting qubits and parametric Josephson devices without mechanical/chemical degradation (e.g., with at most negligible mechanical/chemical degradation) and with reduced physical size and/or spatial footprint. Indeed, as mentioned above, existing techniques involve separately-packaging superconducting qubits and parametric Josephson devices. Such separate packaging prevents undesirable mechanical/chemical degradation of the parametric Josephson devices, at the expense of excessive spatial consumption.

In contrast, various embodiments described herein can address one or more of such technical problems. Specifically, systems/techniques described herein can include bump-bonding a superconducting qubit wafer to a parametric Josephson wafer, and can further include injecting an underfill in between the superconducting qubit wafer and the parametric Josephson wafer. In various instances, such an architecture can consume less space than existing techniques that utilize separate packaging, and the parametric Josephson devices in such an architecture can also experience no and/or negligible mechanical/chemical degradation. More specifically, because the superconducting qubit wafer can be bump-bonded in flip-chip fashion to the parametric Josephson wafer, such architecture can be considered as consuming less physical/geometric space than existing techniques that utilize separate packaging. Indeed, if the superconducting qubit wafer and the parametric Josephson wafer were instead separately packaged, one set of mounting brackets, magnetic shields, and/or cooling apparatuses would be needed for the superconducting qubit wafer, and a duplicative set of mounting brackets, magnetic shields, and/or cooling apparatuses would be needed for the parametric Josephson wafer. In contrast, because the superconducting qubit wafer can be bump-bonded to the parametric Josephson wafer, a single set of mounting brackets, magnetic shields, and/or cooling apparatuses can be sufficient (e.g., the duplicative set of mounting brackets, magnetic shields, and/or cooling apparatuses can be eschewed). Furthermore, although existing techniques for facilitating bump-bonding can cause the parametric Josephson wafer to experience excessive mechanical/chemical degradation during subsequent fabrication/processing of the superconducting qubit wafer, the underfill can prevent such mechanical/chemical degradation from occurring and/or can otherwise reduce such mechanical/chemical degradation to negligible levels. That is, the underfill that is injected between the superconducting qubit wafer and the parametric Josephson wafer can be considered as protecting, safeguarding, and/or otherwise shielding the parametric Josephson wafer from mechanical and/or chemical damage that would otherwise occur during fabrication/processing of the superconducting qubit wafer. Accordingly, the architecture described herein can consume less physical space than existing techniques that rely on separate packaging, without sacrificing the performance of the superconducting qubit wafer and/or of the parametric Josephson wafer. Such an architecture certainly constitutes a concrete and tangible technical improvement in the field of qubits.

As a further benefit, the underfill can, in some cases, even serve to reduce/attenuate electromagnetic crosstalk that would otherwise occur between adjacent parametric Josephson devices on the parametric Josephson wafer. Again, such an architecture certainly constitutes a concrete and tangible technical improvement in the field of qubits.

Moreover, it must be emphasized that, prior to the herein-described teachings, conventional wisdom taught against the use of underfill materials in conjunction with quantum computing hardware. Indeed, it can even be considered as surprising to those having ordinary skill in the art that underfill materials can be used in conjunction with such quantum computing hardware. After all, on the one hand, such underfill materials can typically have very high loss tangents (e.g., on the order of 1E-3), and, on the other hand, quantum circuits can typically be engineered to be ultra-low-loss to maintain maximal qubit coherence. Accordingly, conventional wisdom would counsel against implementing such high-loss underfills with quantum hardware that is intended/desired to be low-loss. However, the present inventors realized that such conventional wisdom was incorrect with respect to parametric Josephson devices. More specifically, the present inventors realized that parametric Josephson devices can be typically more tolerant of loss, since they can often contain dielectrics with comparable loss tangents in their constituent components and can be typically engineered to have low quality factors (or even no resonant structures at all in their traveling-wave geometry). That is, an electromagnetic signal manipulated by and/or otherwise associated with a parametric Josephson device can have limited interactions with lossy elements near such parametric Josephson device. Furthermore, the parametric Josephson devices can be engineered to have limited electromagnetic participation in the underfill (e.g., which can be considered as a lossy element) through the use of lumped element components such as parallel plate capacitors, Josephson junctions, and/or meander inductors. Accordingly, even materials with very high radiofrequency absorption can be used in the underfill without such high loss adversely impacting the parametric Josephson devices. Further still, a superconducting ground plane can be fabricated on the back-side of the superconducting qubit wafer, and such superconducting ground plane can limit undesired electromagnetic interactions of the superconducting qubits with the lossy underfill. In fact, such superconducting ground plane can also serve to impede crosstalk that might otherwise arise between the superconducting qubits of the superconducting qubit wafer and the parametric Josephson devices of the parametric Josephson wafer. In any case, the present inventors devised, contrary to conventional wisdom, a technique for implementing a lossy underfill to physically safeguard parametric Josephson devices from mechanical/chemical degradation without experiencing reduced performance due to the high loss tangent of the underfill. Again, such a technique is certainly a concrete and tangible technical improvement in the field of qubits.

Furthermore, various embodiments described herein can include tangible, hardware-based devices based on the disclosed teachings. For example, embodiments described herein can include tangible qubits (e.g., superconducting qubits made up of Josephson junctions, such as transmon qubits) and/or tangible wafers (e.g., silicon wafers) on which such tangible qubits can be fabricated.

It should be appreciated that the figures and the herein disclosure describe non-limiting examples of various embodiments. It should further be appreciated that the figures are not necessarily drawn to scale.

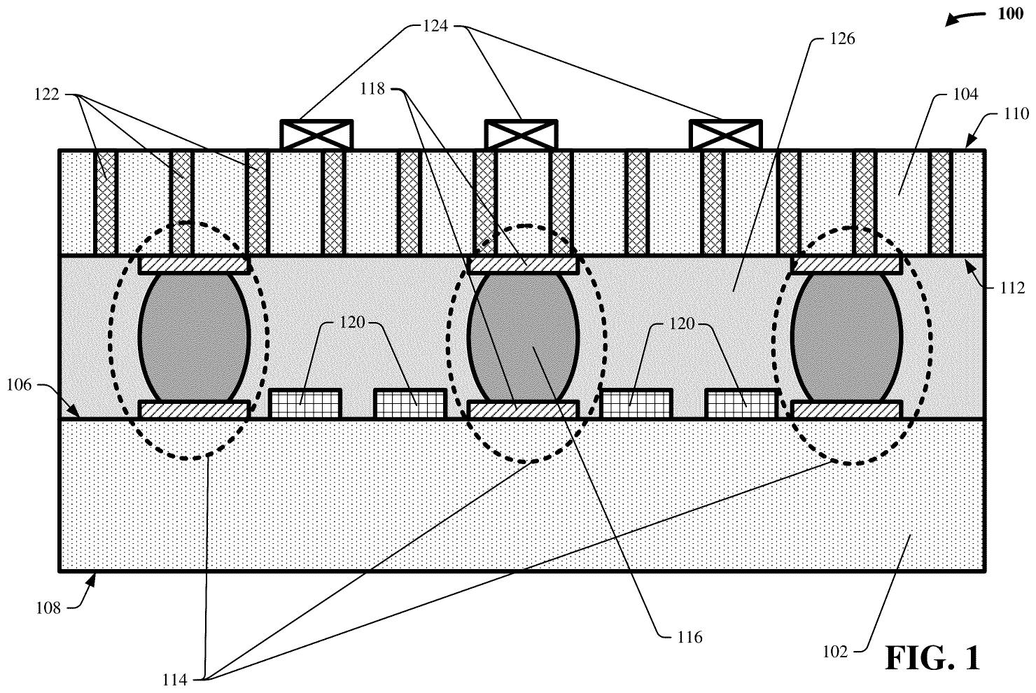

FIG. 1 illustrates a cross-sectional diagram of an example, non-limiting high-density flip-chip co-package 100 for superconducting qubits and parametric Josephson devices in accordance with one or more embodiments described herein. More specifically, FIG. 1 can be considered as depicting a profile-view of the high-density flip-chip co-package 100.

As shown, the high-density flip-chip co-package 100 can include a silicon wafer 102 and a silicon wafer 104. In various aspects, the silicon wafer 102 can have any suitable shape (e.g., rectangular shape, circular shape, triangular shape, hexagonal shape, irregular shape) and/or dimensions (e.g., length, width, thickness) as desired. Likewise, the silicon wafer 104 can have any suitable shape and/or dimensions as desired. In various instances, the silicon wafer 102 and the silicon wafer 104 can have the same and/or different shapes as each other, and/or can have the same and/or different dimensions as each other. In any case, the silicon wafer 102 can be considered as having a first side 106 and a second side 108. Similarly, the silicon wafer 104 can be considered as having a first side 110 and a second side 112.

In various embodiments, as shown, a set of parametric Josephson devices 120 can be fabricated on the first side 106 of the silicon wafer 102. Although FIG. 1 depicts the set of parametric Josephson devices 120 as including four parametric Josephson devices, this is a mere non-limiting example for ease of illustration. In various aspects, the set of parametric Josephson devices 120 can include any suitable number of parametric Josephson devices as desired (e.g., at least one parametric Josephson device). As mentioned above, a parametric device can be any suitable electronic circuit that utilizes a time-varying parameter to couple multiple modes of operation, and a parametric Josephson device can be a parametric device whose time-varying parameter is Josephson inductance. In various instances, one or more of set of parametric Josephson devices 120 can be Josephson travelling-wave parametric amplifiers. In various other instances, one or more of the set of parametric Josephson devices 120 can be Josephson parametric amplifiers. In still other instances, one or more of the set of parametric Josephson devices 120 can be Josephson directional amplifiers. In yet other instances, one or more of the set of parametric Josephson devices 120 can be Josephson parametric converters. In even other instances, one or more of the set of parametric Josephson devices 120 can be Josephson circulators. In various other instances, one or more of the set of parametric Josephson devices 120 can be Josephson isolators. In still various other instances, one or more of the set of parametric Josephson devices 120 can be traveling-wave frequency converters. In yet other various instances, one or more of the set of parametric Josephson devices 120 can be traveling-wave frequency isolators. In some cases, the set of parametric Josephson devices 120 can include any suitable combination and/or combinations of the aforementioned types of parametric Josephson devices. Furthermore, in various cases, any other suitable types of parametric Josephson devices can be included in the set of parametric Josephson devices 120.

In various aspects, the set of parametric Josephson devices 120 can be manufactured on the first side 106 of the silicon wafer 102 by any suitable microfabrication and/or nanofabrication techniques as desired. Non-limiting examples of such microfabrication and/or nanofabrication techniques can include photolithography, deposition, etching, double-angle evaporation, and/or electroplating. In various instances, the set of parametric Josephson devices 120 can be manufactured at any suitable locations and/or positions on/along the first side 106 of the silicon wafer 102 (e.g., the locations/positions of the set of parametric Josephson devices 120 on/along the first side 106 that are depicted in FIG. 1 are mere non-limiting examples for purposes of illustration).

In various aspects, as shown, a set of superconducting qubits 124 can be fabricated on the first side 110 of the silicon wafer 104. Although FIG. 1 depicts the set of superconducting qubits 124 as including three superconducting qubits, this is a mere non-limiting example for ease of illustration. In various cases, the set of superconducting qubits 124 can include any suitable number of superconducting qubits as desired (e.g., at least one superconducting qubit). In various instances, one or more of set of superconducting qubits 124 can be charge qubits. In other instances, one or more of the set of superconducting qubits 124 can be flux qubits. In still other instances, one or more of the set of superconducting qubits 124 can be phase qubits. In yet other instances, one or more of the set of superconducting qubits 124 can be transmon qubits. In even other instances, one or more of the set of superconducting qubits 124 can be xmon qubits. In various other instances, one or more of the set of superconducting qubits 124 can be fluxonium qubits. In still various other instances, one or more of the set of superconducting qubits 124 can be quantronium qubits. In some cases, the set of superconducting qubits 124 can include any suitable combination and/or combinations of the aforementioned types of superconducting qubits. Furthermore, in various cases, any other suitable types of superconducting qubits (e.g., any superconducting qubit architecture that utilizes one or more Josephson junctions) can be included in the set of superconducting qubits 124.

In various aspects, the set of superconducting qubits 124 can be manufactured on the first side 110 of the silicon wafer 104 by any suitable microfabrication and/or nanofabrication techniques as desired. As mentioned above, such microfabrication and/or nanofabrication techniques can, for example, include photolithography, deposition, etching, double-angle evaporation, and/or electroplating. In various cases, the set of superconducting qubits 124 can be manufactured at any suitable locations and/or positions on/along the first side 110 of the silicon wafer 104 (e.g., the locations/positions of the set of superconducting qubits 124 on/along the first side 110 that are depicted in FIG. 1 are mere non-limiting examples for purposes of illustration).

In various aspects, as shown, the silicon wafer 104 can include a set of through-substrate vias 122 that can electrically couple/connect the first side 110 to the second side 112. Although FIG. 1 depicts the set of through-substrate vias 122 as including twelve through-substrate vias, this is a mere non-limiting example for ease of illustration. In various cases, the set of through-substrate vias 122 can include any suitable number of through-substrate vias as desired (e.g., at least one through-substrate via). In various instances, the set of through-substrate vias 122 can be comprised of any suitable superconductive materials as desired (e.g., aluminum, indium, niobium, tin, silver, any suitable alloys thereof). Although FIG. 1 depicts each of the set of through-substrate vias 122 as being made of the same material as each other, this is a mere non-limiting example for ease of illustration. In various cases, different ones of the set of through-substrate vias 122 can be made up of the same and/or different superconducting materials as each other. Furthermore, although FIG. 1 depicts each of the set of through-substrate vias 122 as having the same shapes and/or dimensions as each other, this is a mere non-limiting example for ease of illustration. In various aspects, different ones of the set of through-substrate vias 122 can have the same and/or different shapes/dimensions as each other.

In various aspects, the set of through-substrate vias 122 can be manufactured between the first side 110 and the second side 112 of the silicon wafer 104 by any suitable microfabrication and/or nanofabrication techniques as desired (e.g., photolithography, deposition, etching, double-angle evaporation, electroplating). In various instances, the set of through-substrate vias 122 can be manufactured at any suitable locations and/or positions between the first side 110 and the second side 112 of the silicon wafer 104 (e.g., the locations/positions of the set of through-substrate vias 122 between the first side 110 and the second side 112 that are depicted in FIG. 1 are mere non-limiting examples for purposes of illustration).

In various aspects, as shown, the first side 106 of the silicon wafer 102 can be coupled to the second side 112 of the silicon wafer 104 by a set of bump-bonds 114. Although FIG. 1 depicts the set of bump-bonds 114 as including three bump-bonds, this is a mere non-limiting example for ease of illustration. In various cases, the set of bump-bonds 114 can include any suitable number of bump-bonds as desired (e.g., at least one bump-bond). In various instances, as shown, each of the set of bump-bonds 114 can be comprised of a solder bump 116 that is sandwiched between two under-bump metallizations 118. In various cases, the solder bumps 116 and/or the under-bump metallizations 118 can be made up of any suitable superconducting and/or solder materials as desired. Non-limiting examples of such materials can include indium, indium-tin alloys, indium-silver alloys, tin, and/or lead-tin alloys. In various aspects, the solder bumps 116 and/or the under-bump metallizations 118 can have any suitable shapes and/or dimensions as desired. Although FIG. 1 depicts each of the set of bump-bonds 114 as having the same shapes and/or dimensions as each other, this is a mere non-limiting example for ease of illustration. In various aspects, different ones of the set of bump-bonds 114 can have the same and/or different shapes/dimensions as each other.

In various aspects, the set of bump-bonds 114 can be manufactured by any suitable microfabrication and/or nanofabrication techniques as desired (e.g., photolithography, deposition, etching, double-angle evaporation, electroplating, injection molding). In various instances, the set of bump-bonds 114 can be manufactured at any suitable locations and/or positions between the first side 106 of the silicon wafer 102 and the second side 112 of the silicon wafer 104 (e.g., the locations/positions of the set of bump-bonds 114 between the first side 106 and the second side 112 that are depicted in FIG. 1 are mere non-limiting examples for purposes of illustration).

Although not explicitly shown in FIG. 1, any other suitable superconducting wiring, non-superconductive wiring, coaxial cabling, superconducting circuit structures, non-superconducting circuit structures, and/or dielectric materials/structures can be manufactured on the first side 110 of the silicon wafer 104 as desired, can be manufactured on the second side 112 of the silicon wafer 104 as desired, can be manufactured on the first side 106 of the silicon wafer 102 as desired, can be manufactured on the second side 108 of the silicon wafer 104 as desired, can be manufactured between the first side 110 and the second side 112 of the silicon wafer 104 as desired, and/or can be manufactured between the first side 106 and the second side 108 of the silicon wafer 102 as desired. Such other wiring and/or structures are omitted from FIG. 1 for ease of illustration and/or for purposes of visual clarity.

In various instances, an underfill 126 can be injected in between the first side 106 of the silicon wafer 102 and the second side 112 of the silicon wafer 104, such that the underfill 126 surrounds the set of bump-bonds 114, surrounds/covers the set of parametric Josephson devices 120, and/or separates the silicon wafer 102 from the silicon wafer 104. In various aspects, the underfill 126 can be any suitable thermoset epoxy. That is, the underfill 126 can be any suitable composite material that includes both any suitable epoxy polymer in combination with any suitable amount of any suitable filler. Non-limiting examples of such filler can include silicon dioxide, titanium dioxide, carbon nanotubes, carbon black, and/or graphene. In some instances, the composition of the underfill 126 can be controlled so that a coefficient-of-thermal-expansion of the underfill 126 matches that of the silicon wafer 102 and/or of the silicon wafer 104 (e.g., the silicon wafer 102 and the silicon wafer 104 can have the same coefficient-of-thermal-expansion, since they can both be made of silicon). In any case, the underfill 126 can function and/or serve as a barrier layer that prevents and/or otherwise reduces mechanical stresses and/or chemical corrosion that would otherwise be experienced by the set of parametric Josephson devices 120 during subsequent fabrication/processing of the set of superconducting qubits 124. Furthermore, in various aspects, the underfill 126 can be considered as reducing/ameliorating electromagnetic crosstalk that would otherwise occur between adjacent ones of the set of parametric Josephson devices 120.

Accordingly, the high-density flip-chip co-package 100 can be considered as a physical structure and/or architecture for implementing both the set of superconducting qubits 124 and the set of parametric Josephson devices 120 in a spatially efficient and/or geometrically compact fashion, without the set of parametric Josephson devices 120 being exposed to excessive mechanical/chemical degradation caused by subsequent fabrication/processing of the set of superconducting qubits 124. For at least this reason, the high-density flip-chip co-package 100 can be considered as being advantageous over existing techniques that involve separately packaging the set of superconducting qubits 124 and the set of parametric Josephson devices 120.

Note that, since the set of superconducting qubits 124 can be fabricated on the silicon wafer 104, the silicon wafer 104 can be considered and/or otherwise referred to as a superconducting qubit wafer. Similarly, since the set of parametric Josephson devices 120 can be fabricated on the silicon wafer 102, the silicon wafer 102 can be considered and/or otherwise referred to as a parametric Josephson wafer.

Although not explicitly shown in FIG. 1, the second side 112 of the silicon wafer 104 can be outfitted with any suitable grounded superconducting shields. In various aspects, a grounded superconducting shield can be one or more layers of superconducting materials that are coupled to ground (e.g., that are grounded). In some instances, such one or more layers of superconducting materials can be outfitted with any suitable arrays of holes/vias, which can help to trap magnetic fluxes. In various instances, when one or more grounded superconducting shields are between the second side 112 and the first side 106, such one or more grounded superconducting shields can separate, impede, reduce, and/or otherwise prevent undesirable electromagnetic interactions (e.g., crosstalk) between the set of superconducting qubits 124 and the set of parametric Josephson devices 120. Furthermore, in various aspects, such one or more grounded superconducting shields can separate, impede, reduce, and/or otherwise prevent the set of superconducting qubits 124 from being negatively influenced by a high loss tangent of the underfill 126.

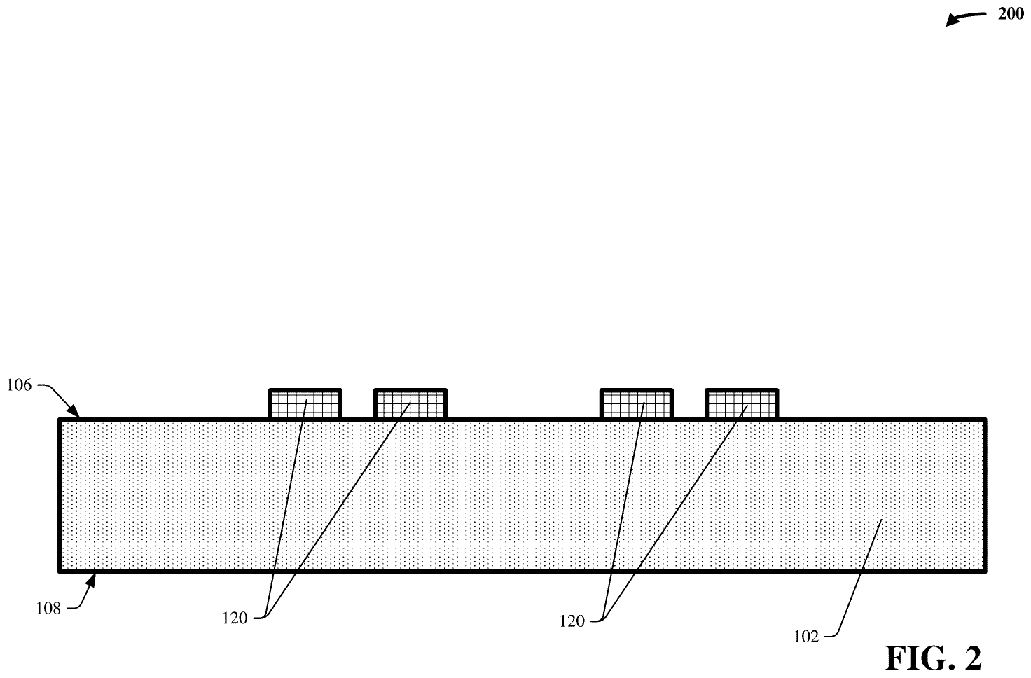

FIGS. 2-13 illustrate example, non-limiting cross-sectional diagrams 200-1300 showing how a high-density flip-chip co-package for superconducting qubits and parametric Josephson devices can be fabricated in accordance with one or more embodiments described herein. More specifically, FIGS. 2-13 depict various intermediate substrate structures that can be involved in the fabrication of the high-density flip-chip co-package 100.

First, consider the cross-sectional diagram 200 of FIG. 2. In various embodiments, as shown, the silicon wafer 102 can be provided and/or obtained in any suitable fashion, and the set of parametric Josephson devices 120 can be manufactured on the first side 106 of the silicon wafer 102. As mentioned above, any suitable microfabrication and/or nanofabrication techniques can be implemented to manufacture the set of parametric Josephson devices 120, such as photolithographic techniques, deposition techniques, etching techniques, dicing techniques, double-angle evaporation techniques, and/or electroplating techniques. Although not explicitly shown in FIG. 2 for ease of illustration and/or for purposes of visual clarity, any other suitable circuit structures can be manufactured on the first side 106 of the silicon wafer 102 by such microfabrication and/or nanofabrication techniques. Non-limiting examples of such other circuit structures can include superconductive wiring, non-superconductive wiring, coaxial cabling, under-bump metallizations, and/or dielectric materials. Likewise, although not explicitly shown in FIG. 2 for ease of illustration and/or for purposes of visual clarity, any of such other suitable circuit structures can be manufactured on the second side 108 of the silicon wafer 102 by such microfabrication and/or nanofabrication techniques. In such cases, although not explicitly shown in FIG. 2 for ease of illustration and/or for purposes of visual clarity, any suitable number of through-substrate vias can be manufactured between the first side 106 and the second side 108 of the silicon wafer 102, so as to electrically connect/couple the first side 106 to the second side 108.

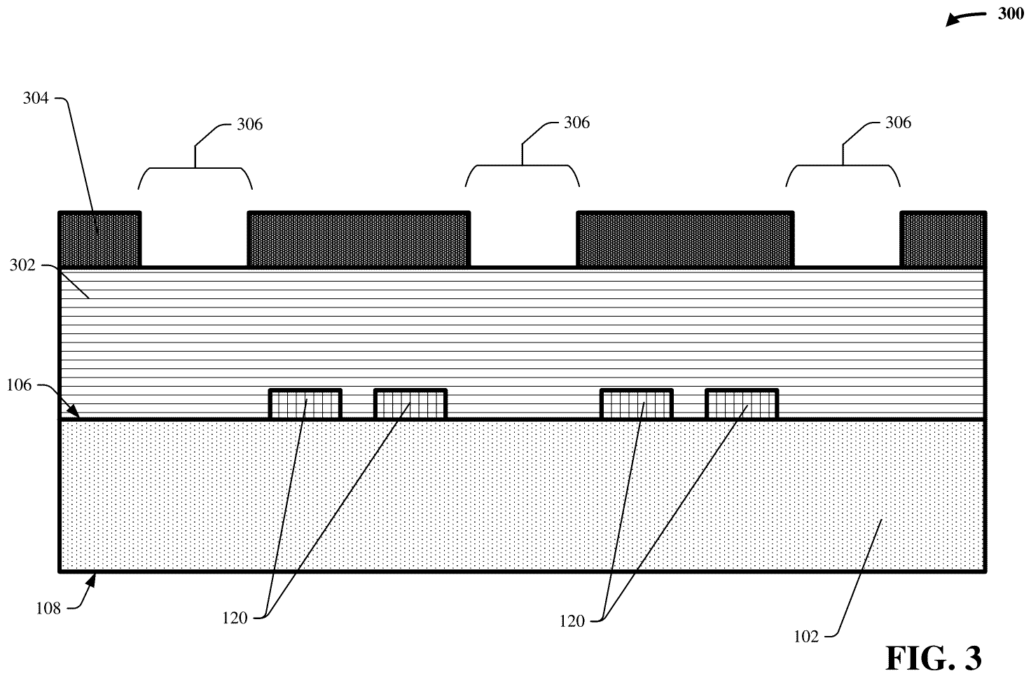

Next, consider the cross-sectional diagram 300 of FIG. 3. In various embodiments, as shown, a photoresist layer 302 can be deposited onto and/or over the first side 106 of the silicon wafer 102. In various aspects, the photoresist layer 302 can be made up of any suitable photoresist materials as desired. For instance, the photoresist layer 302 can be implemented with any suitable polymers, any suitable sensitizers, and/or any suitable solvents. In various cases, the photoresist layer 302 can have any suitable shape and/or dimensions as desired. For example, the photoresist layer 302 can have any suitable thickness, and such thickness can be uniform and/or non-uniform across the photoresist layer 302 as desired. In some cases, the thickness of the photoresist layer 302 can correspond to (e.g., can be equal to and/or otherwise based on) a desired height of each of the set of bump-bonds 114. Although FIG. 3 depicts the top surface of the photoresist layer 302 as being smooth, flat, and/or even, this is a mere non-limiting example for ease of illustration. Indeed, note that, because the photoresist layer 302 can be deposited over top of the set of parametric Josephson devices 120, the top surface of the photoresist layer 302 can, in actuality, be uneven. More specifically, some parts of the photoresist layer 302 can be displaced upward by the set of parametric Josephson devices 120, thereby resulting in raised portions along the top surface of the photoresist layer 302. Such unevenness and/or raised portions are omitted from FIG. 3 for ease of illustration and/or for purposes of visual clarity.

In various aspects, as shown, a patterned mask 304 can be applied and/or positioned above the photoresist layer 302. In various instances, the patterned mask 304 can be made up of any suitable mask material as desired. Moreover, in various cases, the patterned mask 304 can exhibit any suitable shape and/or dimensions as desired. Furthermore, in various aspects, the patterned mask 304 can include a set of cut-outs 306. In various embodiments, the set of cut-outs 306 can be positioned in the patterned mask 304 according to desired locations of the set of bump-bonds 114, and the set of cut-outs 306 can be sized according to desired sizes (e.g., desired widths and/or desired diameters) of the set of bump-bonds 114.

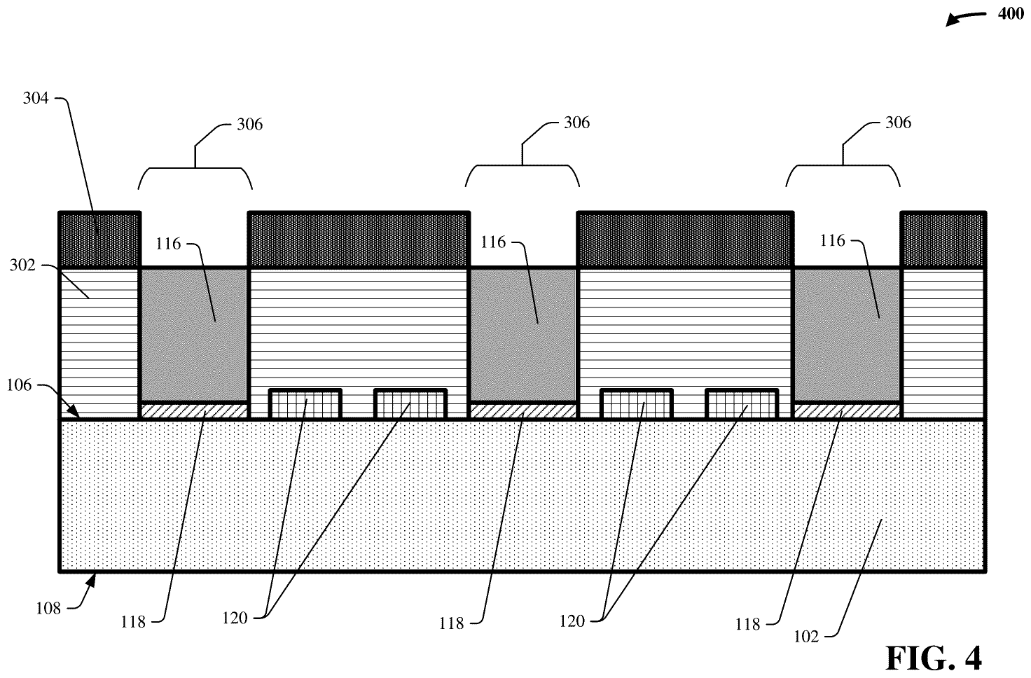

Next, consider the cross-sectional diagram 400 of FIG. 4. In various embodiments, as shown, a set of trenches can be dug within the photoresist layer 302 by applying any suitable etching technique. More specifically, such etching can leave the patterned mask 304 unaffected and can also leave portions of the photoresist layer 302 that are protected by the patterned mask 304 unaffected. However, as shown, other portions of the photoresist layer 302 that are not protected by the patterned mask 304 (e.g., those portions of the photoresist layer 302 that are beneath the set of cut-outs 306) can be removed by such etching. Accordingly, the set of trenches can be positioned in the photoresist layer 302 according to the set of cut-outs 306 (e.g., the set of trenches can correspond to and/or otherwise line up with the set of cut-outs 306). In various cases, each of the set of trenches can penetrate the photoresist layer 302 all the way to the first side 106 of the silicon wafer 102. After such trenches are dug/etched into the photoresist layer 302, a layer of under-bump metallization materials can be deposited within each of the set of trenches above and/or over the first side 106 of the silicon wafer 102, thereby yielding the under-bump metallizations 118. In various aspects, the thickness of the under-bump metallizations 118 can depend upon the extent and/or duration of deposition of the under-bump metallization material, and the shape and/or lateral dimensions of the under-bump metallizations 118 can depend upon the shape and/or dimensions of the set of trenches and/or of the set of cut-outs 306. Likewise, after deposition of the under-bump metallizations 118, a layer of solder material can be deposited within each of the set of trenches above and/or over the under-bump metallizations 118, thereby yielding the solder bumps 116. Again, in various cases, the thickness of the solder bumps 116 can depend upon the extent and/or duration of deposition of the solder bump material, and the shape and/or lateral dimensions of the solder bumps 116 can depend upon the shape and/or dimensions of the set of trenches and/or of the set of cut-outs 306. Although not explicitly shown in FIG. 4, in various cases, such depositions can cause a layer of under-bump metallization material and/or a layer of solder bump material to accumulate above the patterned mask 304 (e.g., above the non-cut-out portions of the patterned mask 304). Such accumulated layers above the patterned mask 304 are omitted from FIG. 4 for ease of illustration and/or for purposes of visual clarity.

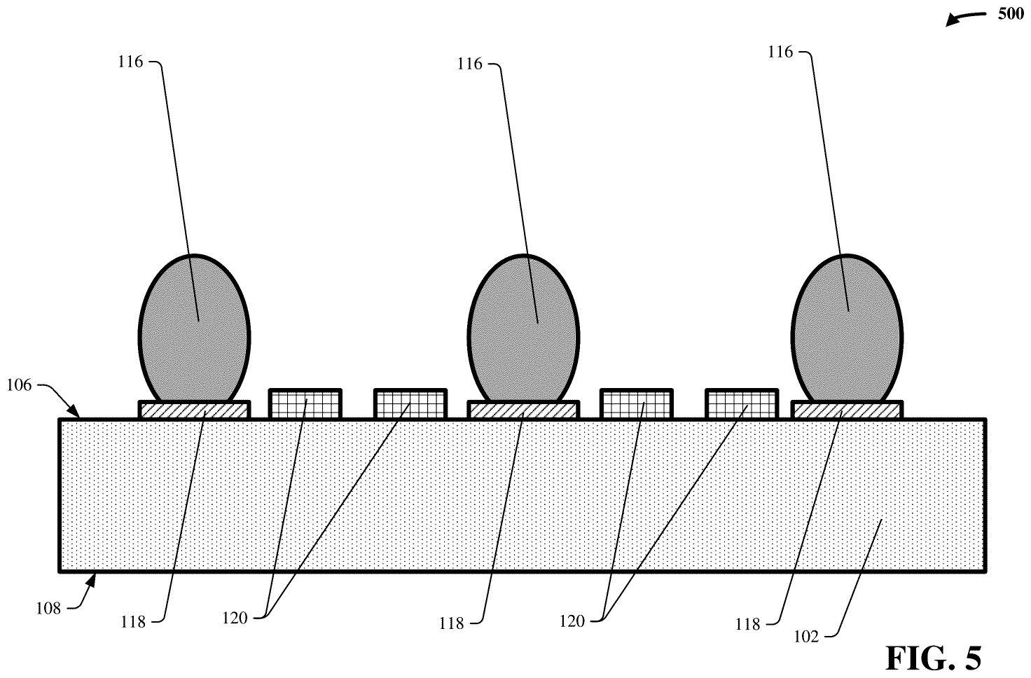

Next, consider the cross-sectional diagram 500 of FIG. 5. In various embodiments, as shown, the photoresist layer 302 and/or the patterned mask 304 (and/or any accumulated layers of under-bump metallization material and/or solder bump material deposited above the patterned mask 304) can be stripped and/or removed via any suitable techniques. Accordingly, the set of parametric Josephson devices 120, the under-bump metallizations 118, and/or the solder bumps 116 can remain on the first side 106 of the silicon wafer 102. Moreover, as shown, the solder bumps 116 can be pre-formed into bump-shapes via any suitable techniques as desired (e.g., reflow, electroplating, stencil printing, injection molding, annealing). In various cases, the silicon wafer 102 can be considered as now ready and/or prepared for bump-bonding.

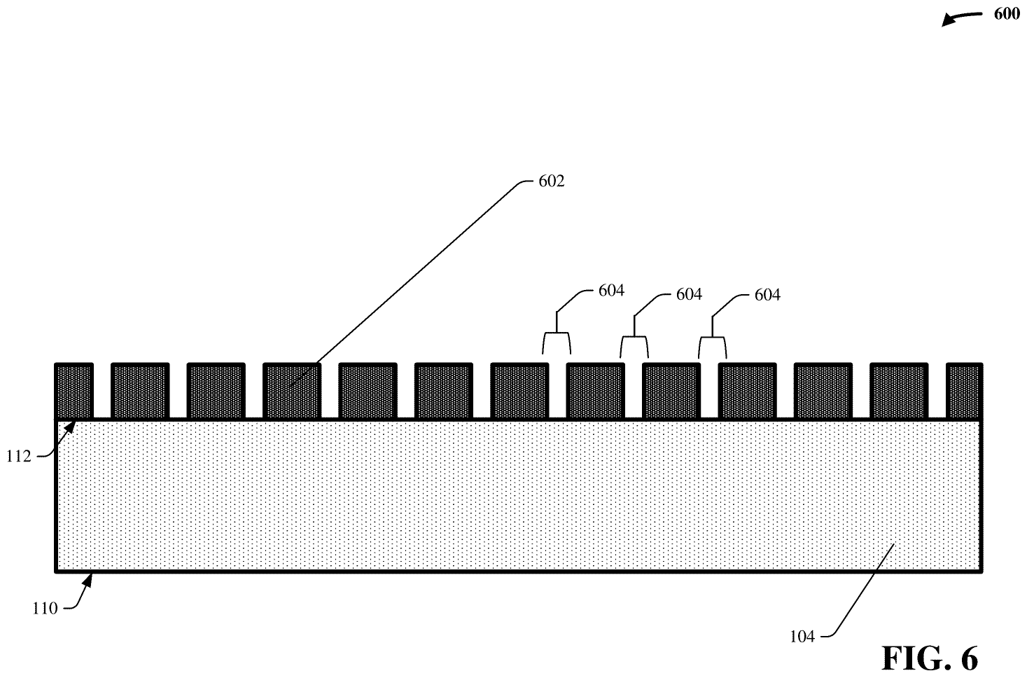

Now, consider the cross-sectional diagram 600 of FIG. 6. In various embodiments, as shown, the silicon wafer 104 can be provided and/or obtained in any suitable fashion, and a patterned mask 602 can be applied and/or positioned above the second side 112 of the silicon wafer 104. In various instances, the patterned mask 602 can be made up of any suitable mask material as desired. Moreover, in various cases, the patterned mask 602 can exhibit any suitable shape and/or dimensions as desired. Furthermore, in various aspects, the patterned mask 602 can include a set of cut-outs 604. In various instances, the set of cut-outs 604 can include any suitable number of cut-outs. In some cases, the set of cut-outs 604 can include one unique/distinct cut-out per unique/distinct through-substrate via in the set of through-substrate vias 122. In various aspects, each of the set of cut-outs 604 can have any suitable shape and/or dimensions (e.g., any suitable length and/or width) as desired. In various cases, the set of cut-outs 604 can be positioned in the patterned mask 602 according to desired locations of the set of through-substrate vias 122, and the set of cut-outs 604 can be sized according to desired sizes (e.g., desired widths and/or desired diameters) of the set of through-substrate vias 122.

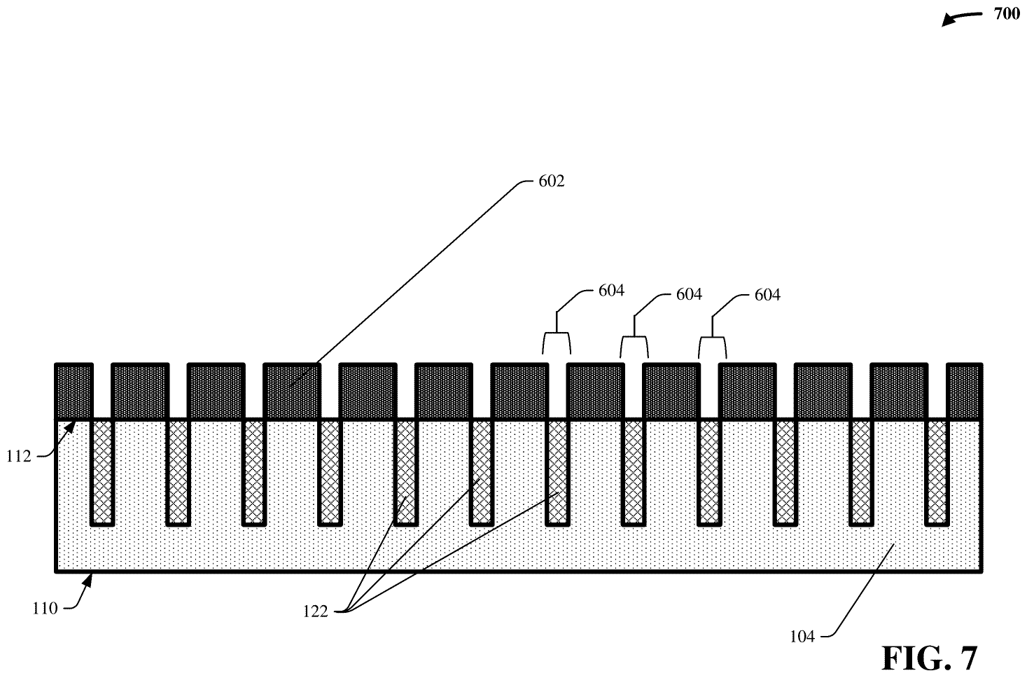

Next, consider the cross-sectional diagram 700 of FIG. 7. In various embodiments, as shown, a set of trenches can be dug within the silicon wafer 104 by applying any suitable etching technique. More specifically, such etching can leave the patterned mask 602 unaffected and can also leave portions of the silicon wafer 104 that are protected by the patterned mask 602 unaffected. However, as shown, other portions of the silicon wafer 104 that are not protected by the patterned mask 602 (e.g., those portions of the silicon wafer 104 that are beneath the set of cut-outs 604) can be removed by such etching. Accordingly, the set of trenches can be positioned in the silicon wafer 104 according to the set of cut-outs 604 (e.g., the set of trenches can correspond to and/or otherwise line up with the set of cut-outs 604). In some cases, as shown, each of the set of trenches can partially penetrate into the silicon wafer 104 from the second side 112 without reaching the first side 110. In other cases, however, any and/or all of the set of trenches can fully penetrate into the silicon wafer 104 from the second side 112 all the way to the first side 110. In any case, after such trenches are dug/etched into the silicon wafer 104, a layer of superconducting material can be deposited within each of the set of trenches of the silicon wafer 104, thereby yielding the set of through-substrate vias 122. In various aspects, the thickness of the set of through-substrate vias 122 can depend upon the extent and/or duration of deposition of the superconducting material, and the shape and/or lateral dimensions of the set of through-substrate vias 122 can depend upon the shape and/or dimensions of the set of trenches and/or of the set of cut-outs 604. Although not explicitly shown in FIG. 7, in various cases, such deposition can cause a layer of superconducting material to accumulate above the patterned mask 602 (e.g., above the non-cut-out portions of the patterned mask 602). Such accumulated layers above the patterned mask 602 are omitted from FIG. 7 for ease of illustration and/or for purposes of visual clarity.

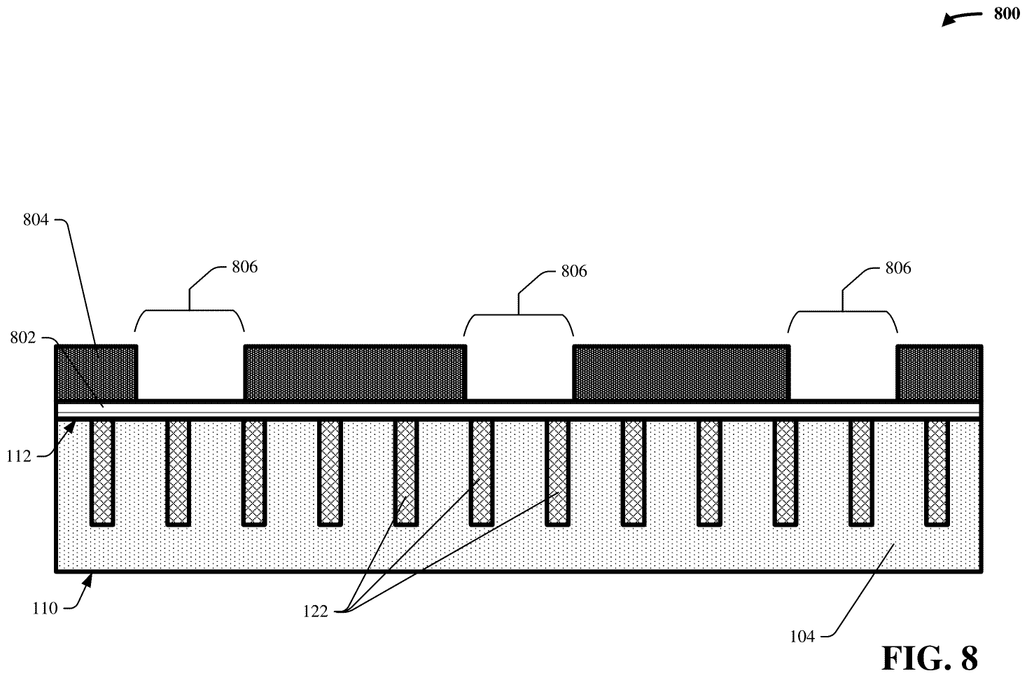

Next, consider the cross-sectional diagram 800 of FIG. 8. In various embodiments, as shown, the patterned mask 602 can be removed, and a photoresist layer 802 can be deposited onto and/or over the second side 112 of the silicon wafer 104. In various aspects, the photoresist layer 802 can be made up of any suitable photoresist materials as desired. For instance, as above, the photoresist layer 802 can be implemented with any suitable polymers, any suitable sensitizers, and/or any suitable solvents. In various cases, also like above, the photoresist layer 802 can have any suitable shape and/or dimensions as desired. For example, the photoresist layer 802 can have any suitable thickness, and such thickness can be uniform and/or non-uniform across the photoresist layer 802. In some cases, the thickness of the photoresist layer 802 can correspond to (e.g., can be equal to and/or otherwise based on) a desired height of each of the set of under-bump metallizations 118.

In various aspects, as shown, a patterned mask 804 can be applied and/or positioned above the photoresist layer 802. In various instances, the patterned mask 804 can be made up of any suitable mask material as desired. Moreover, in various cases, the patterned mask 804 can exhibit any suitable shape and/or dimensions as desired. Furthermore, in various aspects, the patterned mask 804 can include a set of cut-outs 806. In various instances, the set of cut-outs 806 can include any suitable number of cut-outs. In some cases, the set of cut-outs 806 can include one unique/distinct cut-out per unique/distinct bump-bond in the set of bump-bonds 114. In various aspects, each of the set of cut-outs 806 can have any suitable shape and/or dimensions (e.g., any suitable length and/or width) as desired. In various cases, the set of cut-outs 806 can be positioned in the patterned mask 804 according to desired locations of the set of bump-bonds 114, and the set of cut-outs 806 can be sized according to desired sizes (e.g., desired widths and/or desired diameters) of the set of bump-bonds 114.

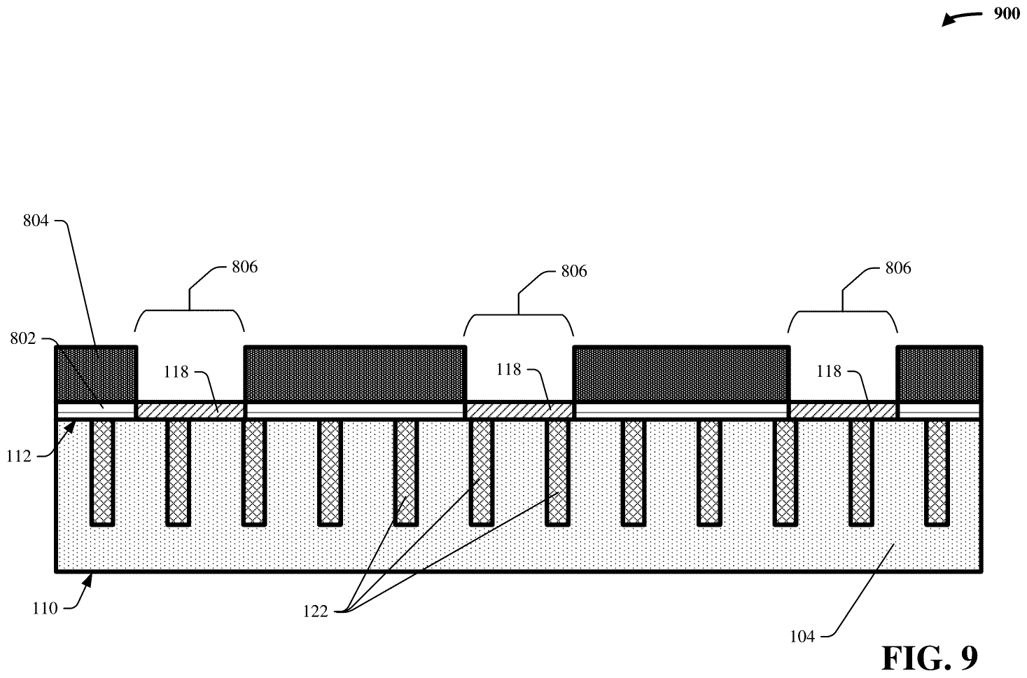

Next, consider the cross-sectional diagram 900 of FIG. 9. In various embodiments, as shown, a set of trenches can be dug within the photoresist layer 802 by applying any suitable etching technique. More specifically, such etching can leave the patterned mask 804 unaffected and can also leave portions of the photoresist layer 802 that are protected by the patterned mask 804 unaffected. However, as shown, other portions of the photoresist layer 802 that are not protected by the patterned mask 804 (e.g., those portions of the photoresist layer 802 that are beneath the set of cut-outs 806) can be removed by such etching. Accordingly, the set of trenches can be positioned in the photoresist layer 802 according to the set of cut-outs 806 (e.g., the set of trenches can correspond to and/or otherwise line up with the set of cut-outs 806). In various cases, each of the set of trenches can penetrate the photoresist layer 802 all the way to the second side 112 of the silicon wafer 104. After such trenches are dug/etched into the photoresist layer 802, a layer of under-bump metallization material can be deposited within each of the set of trenches above and/or over the second side 112 of the silicon wafer 104, thereby yielding the under-bump metallizations 118. In various aspects, the thickness of the under-bump metallizations 118 can depend upon the extent and/or duration of deposition of the under-bump metallization material, and the shape and/or lateral dimensions of the under-bump metallizations 118 can depend upon the shape and/or dimensions of the set of trenches and/or of the set of cut-outs 806. Although not explicitly shown in FIG. 9, in various cases, such deposition can cause a layer of under-bump metallization material to accumulate above the patterned mask 804 (e.g., above the non-cut-out portions of the patterned mask 804). Such accumulated layer above the patterned mask 804 is omitted from FIG. 9 for ease of illustration and/or for purposes of visual clarity.

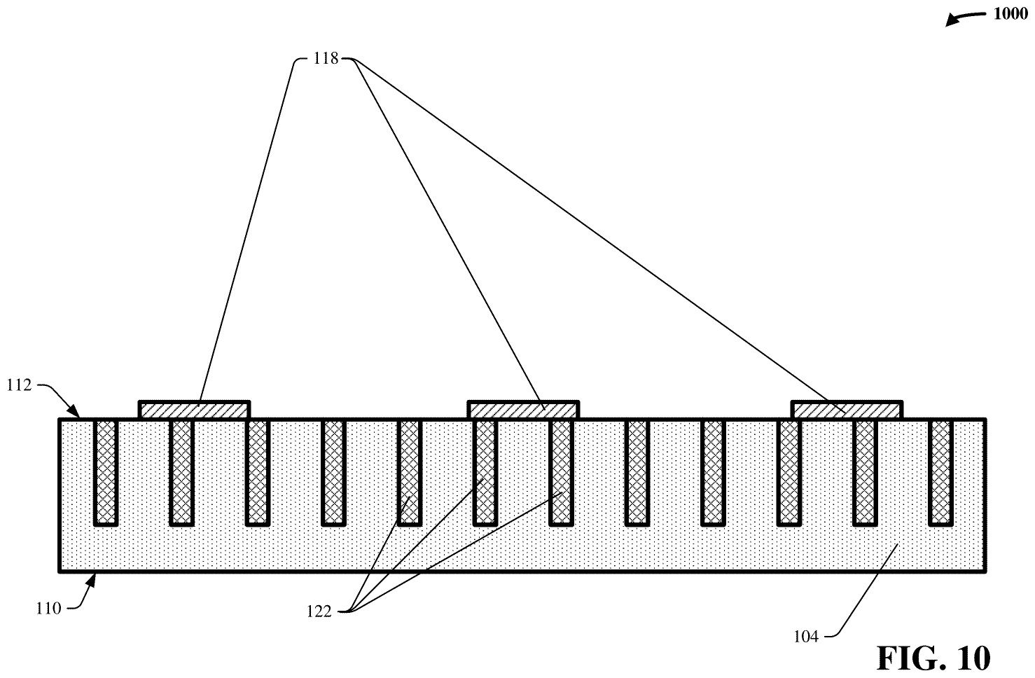

Next, consider the cross-sectional diagram 1000 of FIG. 10. In various embodiments, as shown, the photoresist layer 802 and/or the patterned mask 804 (and/or any accumulated layer of under-bump metallization material deposited above the patterned mask 804) can be stripped and/or removed via any suitable techniques. Accordingly, the under-bump metallizations 118 can remain on the second side 112 of the silicon wafer 104. In various cases, the silicon wafer 104 can be considered as now ready and/or prepared for bump-bonding.

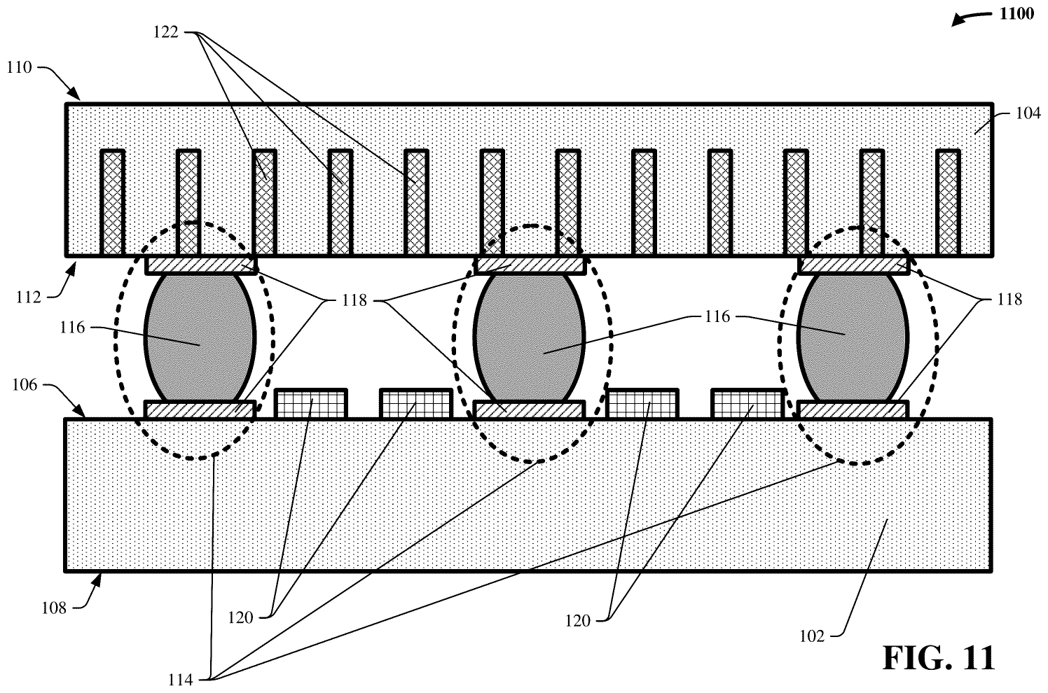

Now, consider the cross-sectional diagram 1100 of FIG. 11. In various embodiments, as shown, the under-bump metallizations 118 on the second side 112 of the silicon wafer 104 can be bonded to the solder bumps 116 on the first side 106 of the silicon wafer 102. In various aspect, any suitable bonding techniques can be implemented to accomplish this. A non-limiting example of such bonding techniques can include reflow bonding using flux or formic acid. Another non-limiting example of such bonding techniques can include thermal compression bonding. Yet another non-limiting example of such bonding techniques can include cold welding. In any case, the result can be that the set of bump-bonds 114 are formed between the first side 106 of the silicon wafer 102 and the second side 112 of the silicon wafer 104, thereby coupling the silicon wafer 102 to the silicon wafer 104.

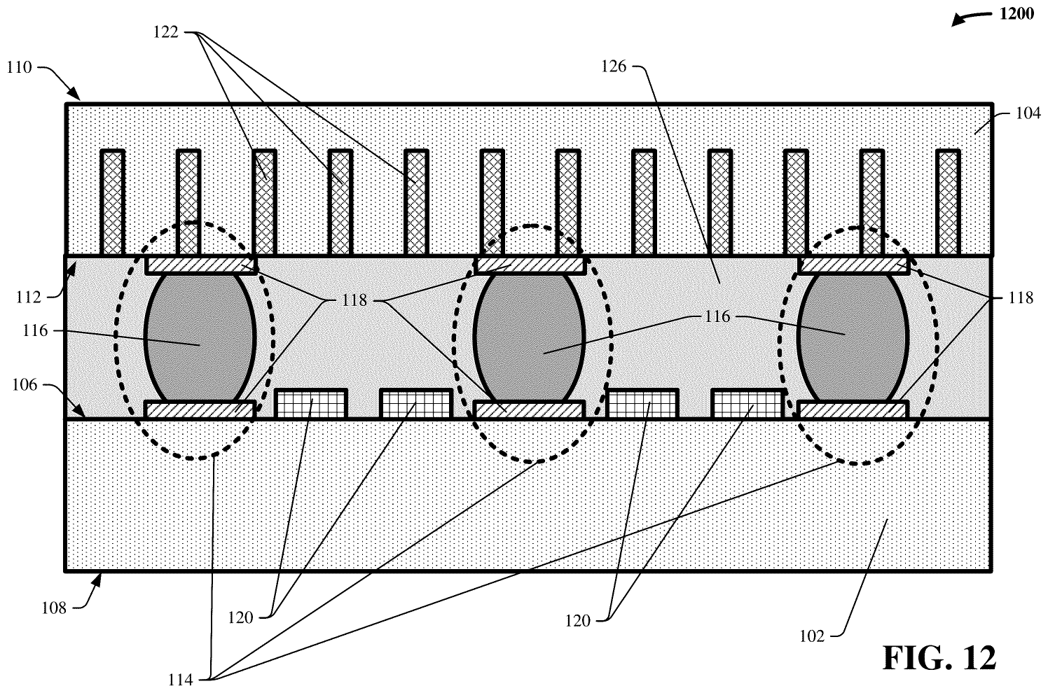

Next, consider the cross-sectional diagram 1200 of FIG. 12. In various embodiments, as shown, although the set of bump-bonds 114 can be considered as coupling the first side 106 of the silicon wafer 102 to the second side 112 of the silicon wafer 104, there can nevertheless be interstitial space and/or interstitial gaps surrounding each of the set of bump-bonds 114 and/or separating the first side 106 of the silicon wafer 102 from the second side 112 of the silicon wafer 104. In various aspects, the underfill 126 can be injected, via any suitable injection technique, into such interstitial space and/or interstitial gaps. Accordingly, the underfill 126 can now be considered as surrounding each of the set of bump-bonds 114, as surrounding each of the set of parametric Josephson devices 120, and/or as separating the first side 106 of the silicon wafer 102 from the second side 112 of the silicon wafer 104. In various instances, any suitable curing techniques can be implemented to cure the underfill 126. In other words, the underfill 126 can be cured at any suitable curing temperature for any suitable curing duration (e.g., high temperature for a short duration, or low temperature for a long duration). As explained above, the underfill 126 can be any suitable thermoset epoxy as desired. That is, the underfill 126 can be any suitable composite that is made up of a filler suspended within an epoxy polymer. Non-limiting examples of the filler can include silicon dioxide, titanium dioxide, carbon nanotubes, carbon black, and/or graphene. In various instances, the underfill 126 can exhibit any suitable proportion of filler to epoxy polymer.

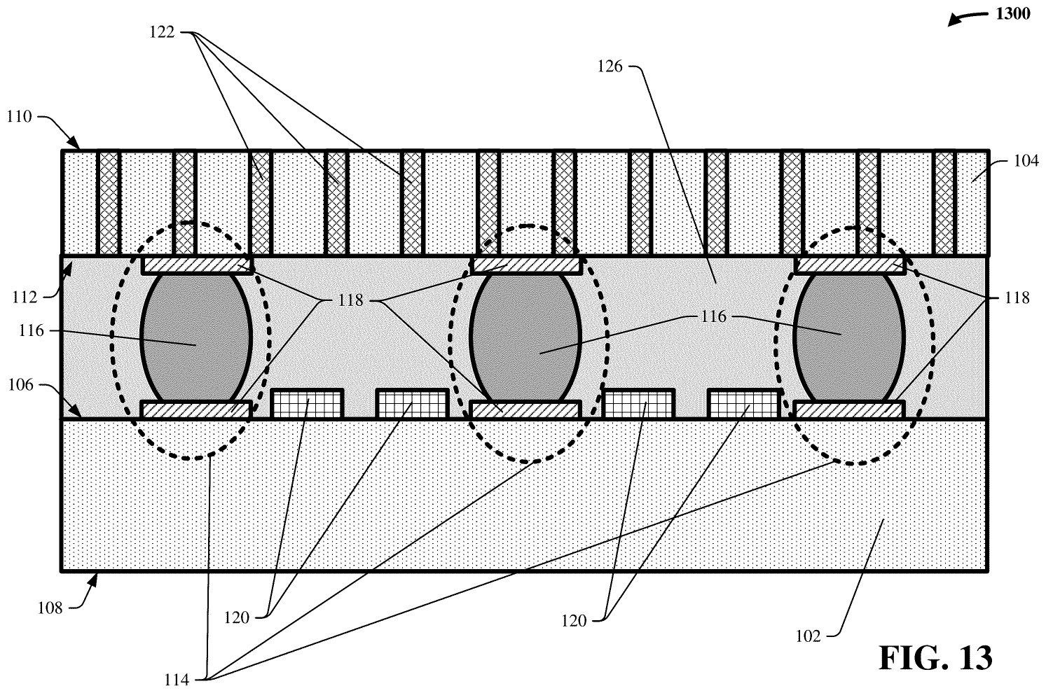

Next, consider the cross-sectional diagram 1300 of FIG. 13. As mentioned above, the set of through-substrate vias 122 can, in some cases, be fabricated so as to initially not fully penetrate from the second side 112 of the silicon wafer 104 to the first side 110 of the silicon wafer 104. In such cases, as shown in FIG. 13, the first side 110 of the silicon wafer 104 can be ground down, via any suitable grinding techniques, so as to reveal the set of through-substrate vias 122. In other words, grinding can be facilitated after the silicon wafer 104 has been bump-bonded to the silicon wafer 102, so as to reduce the thickness of the silicon wafer 104 (e.g., so as to bring the first side 110 closer to the second side 112), which can reveal the set of through-substrate vias 122 in the first side 110. However, such grinding can be unnecessary in cases where the set of through-substrate vias 122 have already been fabricated to fully penetrate the silicon wafer 104 from the second side 112 to the first side 110.

In any case, after the set of through-substrate vias 122 are revealed in the first side 110 of the silicon wafer 104, the set of superconducting qubits 124 can be manufactured on the first side 110 of the silicon wafer 104. As mentioned above, any suitable microfabrication and/or nanofabrication techniques can be implemented to manufacture the set of superconducting qubits 124, such as photolithographic techniques, deposition techniques, etching techniques, dicing techniques, double-angle evaporation techniques, and/or electroplating techniques. Although not explicitly shown in FIG. 13 for ease of illustration and/or for purposes of visual clarity, any other suitable circuit structures can be manufactured on the first side 110 of the silicon wafer 104 by such microfabrication and/or nanofabrication techniques. Non-limiting examples of such other circuit structures can include superconductive wiring, non-superconductive wiring, coaxial cabling, under-bump metallizations, and/or dielectric materials. Note that the underfill 126 can be considered as protecting the set of parametric Josephson devices 120 during such microfabrication and/or nanofabrication. In other words, the underfill 126 can be considered as a protective barrier that safeguards the set of parametric Josephson devices 120 during subsequent fabrication processing (e.g., the underfill 126 can prevent the set of parametric Josephson devices 120 from being mechanically and/or chemically damaged during grinding of the silicon wafer 104 and/or during fabrication of the set of superconducting qubits 124) In various aspects, the result of such fabrication can be the high-density flip-chip co-package 100, as shown in FIG. 1.

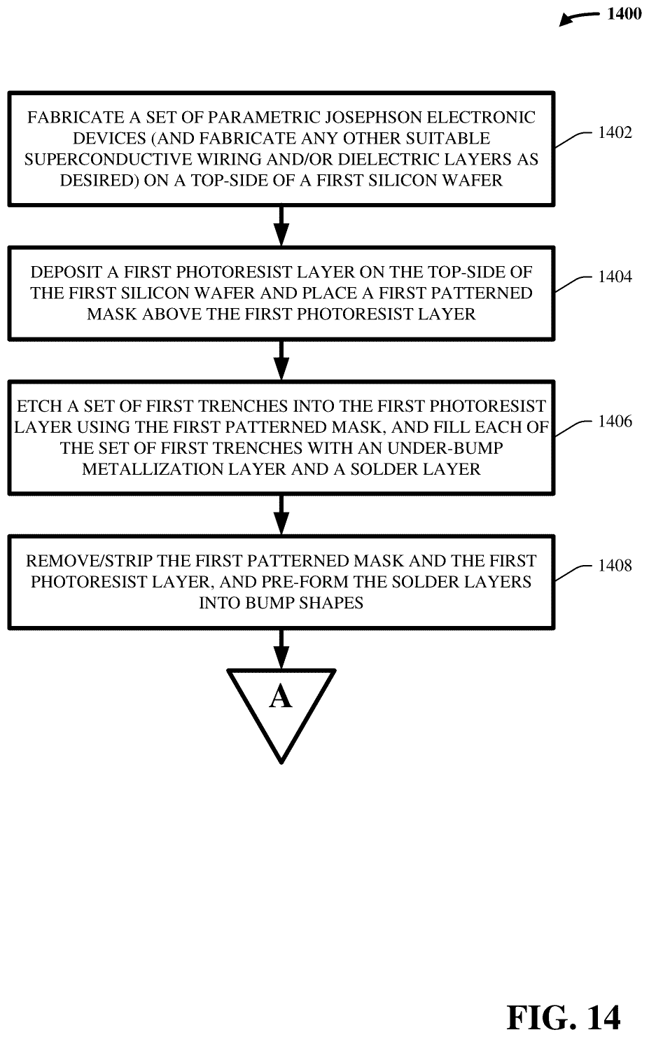

FIGS. 14-16 illustrate example, non-limiting block diagrams 1400, 1500, and 1600 explaining how a high-density flip-chip co-package for superconducting qubits and parametric Josephson devices can be fabricated in accordance with one or more embodiments described herein. That is, FIGS. 14-16 help to explain how the high-density flip-chip co-package 100 can be manufactured.

First, consider the block diagram 1400 of FIG. 14. In various embodiments, act 1402 can include fabricating a set of parametric Josephson devices (e.g., 120) on a first side (e.g., 106) of a first silicon wafer (e.g., 102). In some cases, this can include fabricating any other suitable superconductive wiring, coaxial cabling, dielectric layers, and/or circuit structures as desired on the first side of the first silicon wafer.

In various aspects, act 1404 can include depositing a first photoresist layer (e.g., 302) on the first side of the first silicon wafer and placing a first patterned mask (e.g., 304) above the first photoresist layer.

In various instances, act 1406 can include etching a set of first trenches (e.g., trenches formed due to 306) into the first photoresist layer using the first patterned mask, and filling each of the set of first trenches with an under-bump metallization layer (e.g., 118) and/or a solder layer (e.g., 116).

In various cases, act 1408 can include removing/stripping the first patterned mask and/or the first photoresist layer from the first side of the first silicon wafer, and pre-forming the solder layers into bump-shapes.

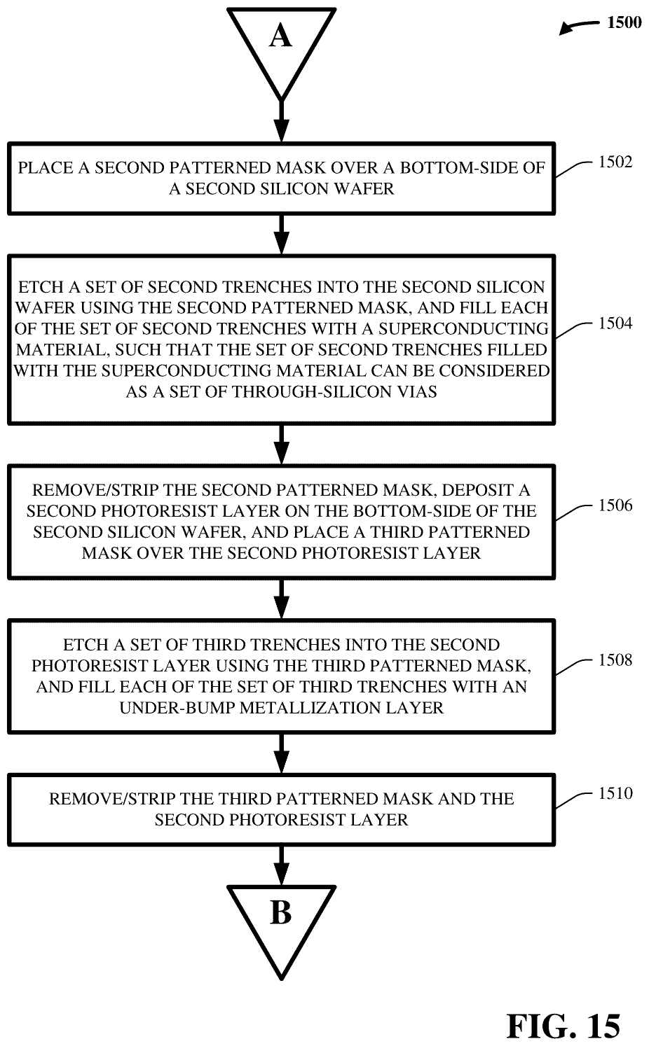

Now, consider the block diagram 1500 of FIG. 15. In various embodiments, act 1502 can include placing a second patterned mask (e.g., 602) over a second side (e.g., 112) of a second silicon wafer (e.g., 104).

In various aspects, act 1504 can include etching a set of second trenches (e.g., trenches formed due to 604) into the second silicon wafer using the second patterned mask, and filling each of the set of second trenches with a superconducting material. Accordingly, the set of second trenches filled with the superconducting material can be considered as a set of through-substrate vias (e.g., 122).

In various instances, act 1506 can include removing/stripping the second patterned mask, depositing a second photoresist layer (e.g., 802) on the second side of the second silicon wafer, and placing a third patterned mask (e.g., 804) on the second photoresist layer.

In various cases, act 1508 can include etching a set of third trenches (e.g., trenches formed due to 806) into the second photoresist layer using the third patterned mask, and filling each of the set of third trenches with an under-bump metallization layer (e.g., 118).

In various aspects, act 1510 can include removing/stripping the third patterned mask and the second photoresist layer from the second side of the second silicon wafer.

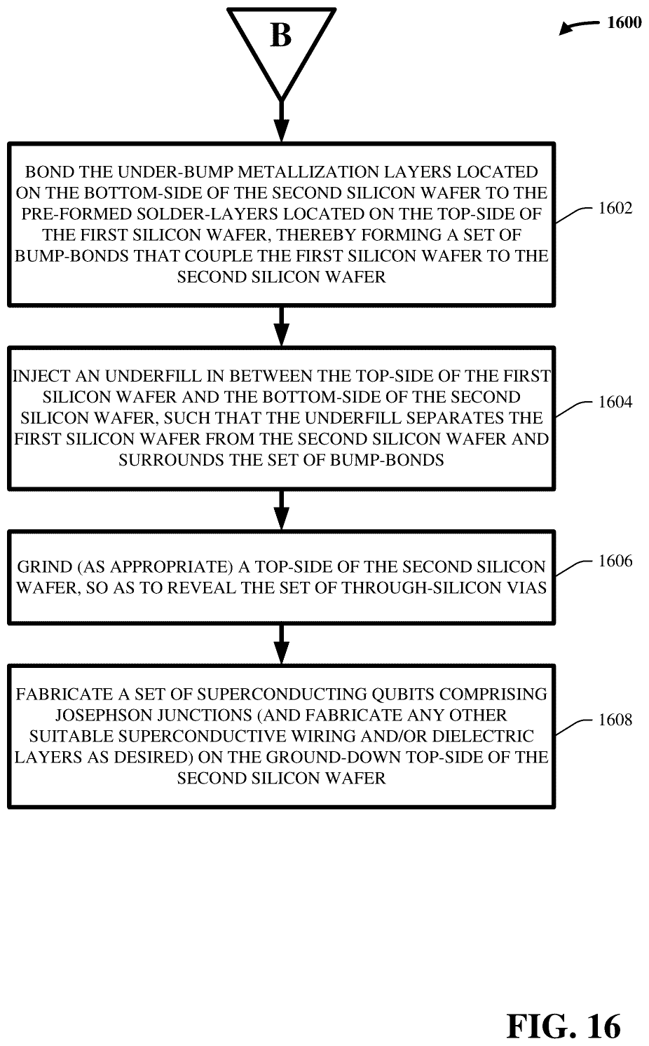

Now, consider the block diagram 1600 of FIG. 16. In various embodiments, act 1602 can include bonding the under-bump metallization layers located on the second side of the second silicon wafer to the pre-formed solder-layers located on the first side of the first silicon wafer. This can form a set of bump-bonds (e.g., 114) that couple the first silicon wafer to the second silicon wafer.

In various aspects, act 1604 can include injecting an underfill (e.g., 126) in between the first side of the first silicon wafer and the second side of the second silicon wafer. Accordingly, the underfill can be considered as separating the first silicon wafer from the second silicon wafer and/or as surrounding the set of bump-bonds.

In various instances, act 1606 can include grinding, as appropriate and/or as needed, a first side (e.g., 110) of the second silicon wafer, so as to reveal the set of through-substrate vias. If the set of through-substrate vias are already revealed through the first side of the second silicon wafer, then such grinding can be skipped.

In various cases, act 1608 can include fabricating a set of superconducting qubits (e.g., 124) comprising Josephson junctions on the ground-down first side of the second silicon wafer. In some cases, this can include fabricating any other suitable superconductive wiring, coaxial cabling, dielectric layers, and/or circuit structures as desired on the ground-down first side of the second silicon wafer.

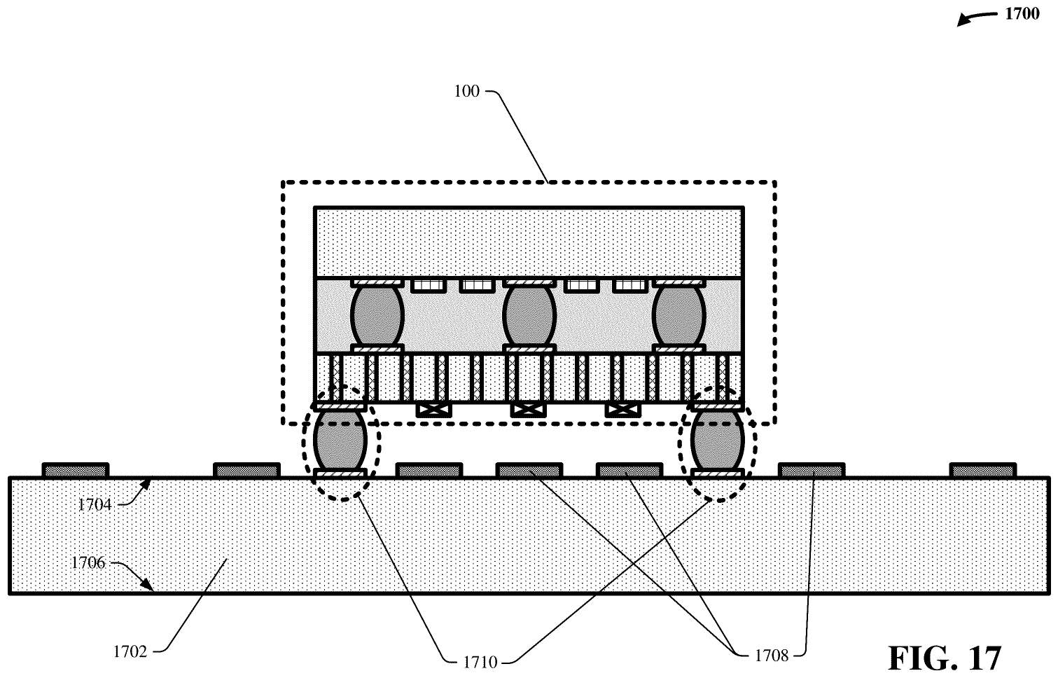

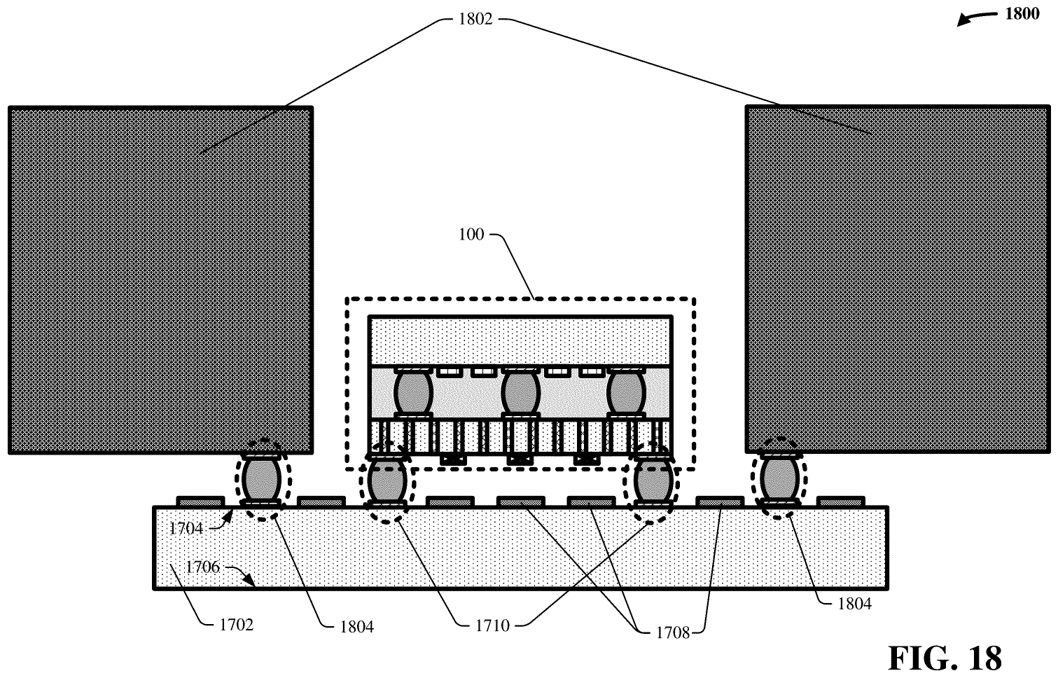

FIGS. 17-18 illustrate example, non-limiting cross-sectional diagrams 1700-1800 showing how a high-density flip-chip co-package for superconducting qubits and parametric Josephson devices can be coupled to an interposer and/or an organic substrate in accordance with one or more embodiments described herein.

First, consider the cross-sectional diagram 1700 of FIG. 17. In various embodiments, as shown, there can be an interposer wafer 1702. In various aspects, the interposer wafer 1702 can have any suitable shape (e.g., rectangular shape, circular shape, triangular shape, hexagonal shape, irregular shape) and/or dimensions (e.g., length, width, thickness) as desired. In various instances, the interposer wafer 1702 can be made up of any suitable quantum computing substrate materials as desired (e.g., silicon). In any case, the interposer wafer 1702 can be considered as having a first side 1704 and a second side 1706.

In various embodiments, as shown, a set of resonators 1708 can be fabricated on the first side 1704 of the interposer wafer 1702. Although FIG. 17 depicts the set of resonators 1708 as including seven resonators, this is a mere non-limiting example for ease of illustration. In various aspects, the set of resonators 1708 can include any suitable number of resonators as desired (e.g., at least one resonator). In various instances, the set of resonators 1708 can include any suitable type and/or types of resonators (e.g., quantum readout resonators) exhibiting any suitable resonator architectures as desired. In various cases, the set of resonators 1708 can be manufactured on the first side 1704 of the interposer wafer 1702 by any suitable microfabrication and/or nanofabrication techniques as desired (e.g., photolithography, deposition, etching, double-angle evaporation, electroplating). In various instances, the set of resonators 1708 can be manufactured at any suitable locations and/or positions on/along the first side 1704 of the interposer wafer 1702 (e.g., the locations/positions of the set of resonators 1708 on/along the first side 1704 that are depicted in FIG. 17 are mere non-limiting examples for purposes of illustration).

In various aspects, as shown, the high-density flip-chip co-package 100 can be bump-bonded to the interposer wafer 1702. More specifically, a set of bump-bonds 1710 can couple the first side 110 of the silicon wafer 104 to the first side 1704 of the interposer wafer 1702. Although FIG. 17 depicts the set of bump-bonds 1710 as including two bump-bonds, this is a mere non-limiting example for ease of illustration. In various instances the set of bump-bonds 1710 can include any suitable number of bump-bonds as desired (e.g., at least one bump-bond). In various instances, as shown, each of the set of bump-bonds 1710 can be comprised of a solder bump that is sandwiched between two under-bump metallizations, just like each of the set of bump-bonds 114. Although FIG. 17 depicts each of the set of bump-bonds 1710 as having the same shapes, dimensions, and/or compositions as each of the set of bump-bonds 114, this is a mere non-limiting example for ease of illustration. In various cases, any of the set of bump-bonds 1710 can have the same and/or different shapes, dimensions, and/or compositions as any of the set of bump-bonds 114. Indeed, in some cases, the set of bump-bonds 114 can be physically smaller than each of the set of bump-bonds 1710, which can be beneficial for saving space. In various aspects, the set of bump-bonds 1710 can be manufactured by any suitable microfabrication and/or nanofabrication techniques as desired (e.g., photolithography, deposition, etching, double-angle evaporation, electroplating). In various instances, the set of bump-bonds 1710 can be manufactured at any suitable locations and/or positions between the first side 110 of the silicon wafer 104 and the first side 1704 of the interposer wafer 1702 (e.g., the locations/positions of the set of bump-bonds 1710 between the first side 110 and the first side 1704 that are depicted in FIG. 17 are mere non-limiting examples for purposes of illustration).

Although not explicitly shown in FIG. 17, any other suitable superconducting wiring, non-superconductive wiring, coaxial cabling, superconducting circuit structures, non-superconducting circuit structures, and/or dielectric materials/structures can be manufactured on the first side 1704 of the interposer wafer 1702 as desired, can be manufactured on the second side 1706 of the interposer wafer 1702 as desired, and/or can be manufactured between the first side 1704 and the second side 1706 of the interposer wafer 1702 as desired. Such other wiring and/or structures are omitted from FIG. 17 for ease of illustration and/or for purposes of visual clarity.

Next, consider the cross-sectional diagram 1800 of FIG. 18. In various embodiments, as shown, there can be an organic substrate 1802. In various aspects, the organic substrate 1802 can have any suitable shape (e.g., rectangular shape, circular shape, triangular shape, hexagonal shape, irregular shape) and/or dimensions (e.g., length, width, thickness) as desired. In various instances, the organic substrate 1802 can be made up of any suitable materials as desired. As some non-limiting examples, the organic substrate 1802 can be a printed circuit board, a flexible printed circuit board, and/or a laminate. Although not explicitly shown in FIG. 18, any other suitable superconductive wiring, non-superconductive wiring, coaxial cabling, superconductive circuit structures, non-superconductive circuit structures, and/or dielectric materials/layers can be fabricated on the organic substrate 1802. Such other wiring/structures/layers are omitted from FIG. 18 for ease of illustration and/or for purposes of visual clarity.

In any case, as shown, the interposer wafer 1702 can be bump-bonded to the organic substrate 1802. More specifically, a set of bump-bonds 1804 can couple the first side 1704 of the interposer wafer 1702 to the organic substrate 1802. Although FIG. 18 depicts the set of bump-bonds 1804 as including two bump-bonds, this is a mere non-limiting example for ease of illustration. In various aspects, the set of bump-bonds 1804 can include any suitable number of bump-bonds as desired (e.g., at least one bump-bond). In various instances, as shown, each of the set of bump-bonds 1804 can be comprised of a solder bump that is sandwiched between two under-bump metallizations, just like each of the set of bump-bonds 114 and/or just like each of the set of bump-bonds 1710. Although FIG. 18 depicts each of the set of bump-bonds 1804 as having the same shapes, dimensions, and/or compositions as each of the set of bump-bonds 114 and/or as each of the set of bump-bonds 1710, this is a mere non-limiting example for ease of illustration. In various cases, any of the set of bump-bonds 1804 can have the same and/or different shapes, dimensions, and/or compositions as any of the set of bump-bonds 114 and/or as any of the set of bump-bonds 1710. In various aspects, the set of bump-bonds 1804 can be manufactured by any suitable microfabrication and/or nanofabrication techniques as desired (e.g., photolithography, deposition, etching, double-angle evaporation, electroplating). In various instances, the set of bump-bonds 1804 can be manufactured at any suitable locations and/or positions between the first side 1704 of the interposer wafer 1702 and the organic substrate 1802 (e.g., the locations/positions of the set of bump-bonds 1804 between the first side 1704 and the organic substrate 1802 that are depicted in FIG. 18 are mere non-limiting examples for purposes of illustration).

Although FIGS. 17-18 depict a single instance of the high-density flip-chip co-package 100 being bump-bonded to the interposer wafer 1702, this is a mere non-limiting example for ease of illustration. In various aspects, any suitable number of high-density flip-chip co-packages (e.g., two or more instances and/or copies of the high-density flip-chip co-package 100) can be bump-bonded to the first side 1704 of the interposer wafer 1702.

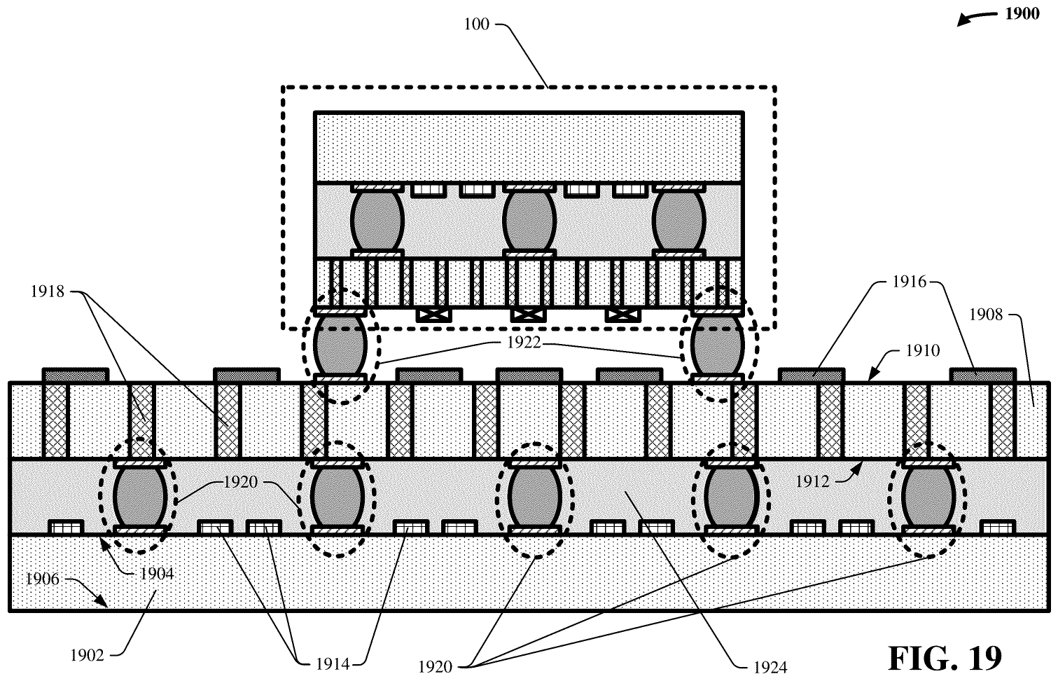

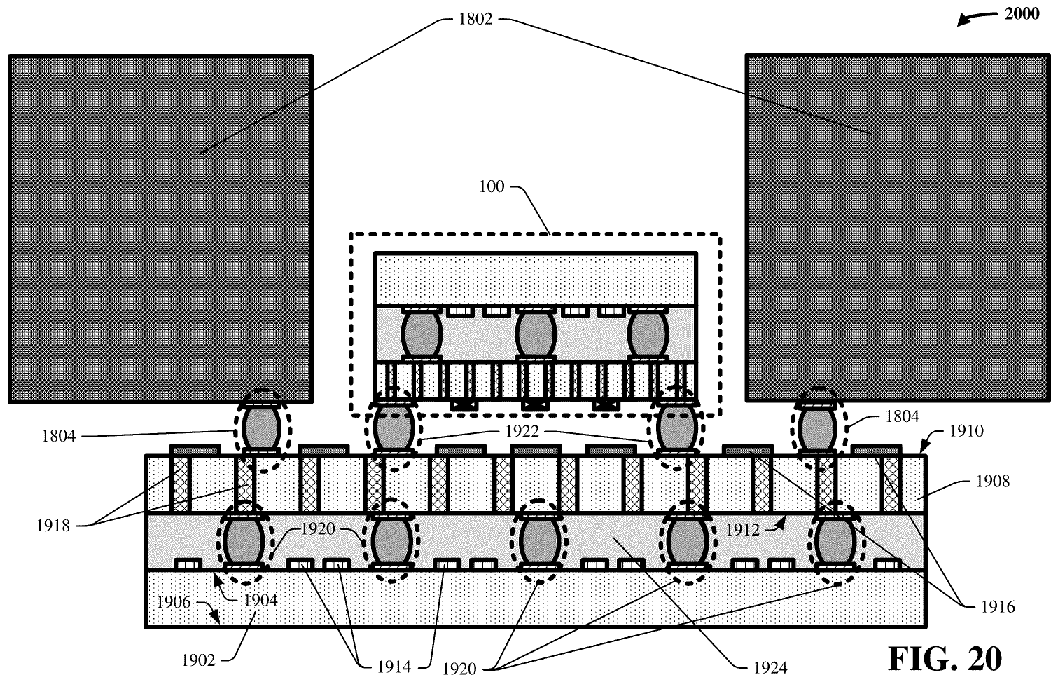

FIGS. 19-20 illustrate example, non-limiting cross-sectional diagrams showing how a high-density flip-chip co-package for superconducting qubits and parametric Josephson devices can be coupled to an alternative interposer and/or an organic substrate in accordance with one or more embodiments described herein.

First, consider the cross-sectional diagram 1900 of FIG. 19. In various embodiments, as shown, there can be an interposer wafer 1902 and an interposer wafer 1908. In various aspects, the interposer wafer 1902 can have any suitable shape (e.g., rectangular shape, circular shape, triangular shape, hexagonal shape, irregular shape) and/or dimensions (e.g., length, width, thickness) as desired. Likewise, the interposer wafer 1908 can have any suitable shape and/or dimensions as desired. In various instances, the interposer wafer 1902 and the interposer wafer 1908 can have the same and/or different shapes as each other, and/or can have the same and/or different dimensions as each other. In any case, the interposer wafer 1902 can be considered as having a first side 1904 and a second side 1906. Similarly, the interposer wafer 1908 can be considered as having a first side 1910 and a second side 1912. Moreover, in various aspects, the interposer wafer 1902 and/or the interposer wafer 1908 can be made up of any suitable quantum computing substrate materials as desired (e.g., both can be made of silicon).

In various embodiments, as shown, a set of parametric Josephson devices 1914 can be fabricated on the first side 1904 of the interposer wafer 1902. Although FIG. 19 depicts the set of parametric Josephson devices 1914 as including ten parametric Josephson devices, this is a mere non-limiting example for ease of illustration. In various cases, the set of parametric Josephson devices 1914 can include any suitable number of parametric Josephson devices as desired (e.g., at least one parametric Josephson device). In various instances, one or more of set of parametric Josephson devices 1914 can be Josephson travelling-wave parametric amplifiers, Josephson parametric amplifiers, Josephson directional amplifiers, Josephson parametric converters, Josephson circulators, Josephson isolators, traveling-wave frequency converters, traveling-wave frequency isolators, any suitable combination and/or combinations thereof, and/or any other suitable types of parametric Josephson devices. In various aspects, the set of parametric Josephson devices 1914 can be manufactured on the first side 1904 of the interposer wafer 1902 by any suitable microfabrication and/or nanofabrication techniques as desired (e.g., photolithography, deposition, etching, double-angle evaporation, electroplating). In various cases, the set of parametric Josephson devices 1914 can be manufactured at any suitable locations and/or positions on/along the first side 1904 of the interposer wafer 1902 (e.g., the locations/positions of the set of parametric Josephson devices 1914 on/along the first side 1904 that are depicted in FIG. 19 are mere non-limiting examples for purposes of illustration).

In various aspects, as shown, a set of resonators 1916 can be fabricated on the first side 1910 of the interposer wafer 1908. Although FIG. 19 depicts the set of resonators 1916 as including seven resonators, this is a mere non-limiting example for ease of illustration. In various cases, the set of resonators 1916 can include any suitable number of resonators as desired (e.g., at least one resonator). In various instances, the set of resonators 1916 can include any suitable type and/or types of resonators (e.g., quantum readout resonators) exhibiting any suitable resonator architectures as desired. In various cases, the set of resonators 1916 can be manufactured on the first side 1910 of the interposer wafer 1908 by any suitable microfabrication and/or nanofabrication techniques as desired (e.g., photolithography, deposition, etching, double-angle evaporation, electroplating). In various instances, the set of resonators 1916 can be manufactured at any suitable locations and/or positions on/along the first side 1910 of the interposer wafer 1908 (e.g., the locations/positions of the set of resonators 1916 on/along the first side 1910 that are depicted in FIG. 19 are mere non-limiting examples for purposes of illustration).

In various aspects, as shown, the interposer wafer 1908 can include a set of through-substrate vias 1918 that can electrically couple/connect the first side 1910 to the second side 1912. Although FIG. 19 depicts the set of through-substrate vias 1918 as including twelve through-substrate vias, this is a mere non-limiting example for ease of illustration. In various aspects, the set of through-substrate vias 1918 can include any suitable number of through-substrate vias as desired (e.g., at least one through-substrate via). In various instances, the set of through-substrate vias 1918 can be comprised of any suitable superconductive materials as desired. Although FIG. 19 depicts each of the set of through-substrate vias 1918 as being made of the same material as each other, this is a mere non-limiting example for ease of illustration. In various cases, different ones of the set of through-substrate vias 1918 can be made up of the same and/or different superconducting materials as each other. Furthermore, although FIG. 19 depicts each of the set of through-substrate vias 1918 as having the same shapes and/or dimensions as each other, this is a mere non-limiting example for ease of illustration. In various aspects, different ones of the set of through-substrate vias 1918 can have the same and/or different shapes/dimensions as each other. In various cases, the set of through-substrate vias 1918 can be manufactured between the first side 1910 and the second side 1912 of the interposer wafer 1908 by any suitable microfabrication and/or nanofabrication techniques as desired (e.g., photolithography, deposition, etching, double-angle evaporation, electroplating). In various instances, the set of through-substrate vias 1918 can be manufactured at any suitable locations and/or positions between the first side 1910 and the second side 1912 of the interposer wafer 1908 (e.g., the locations/positions of the set of through-substrate vias 1918 between the first side 1910 and the second side 1912 that are depicted in FIG. 19 are mere non-limiting examples for purposes of illustration).

In various aspects, as shown, the first side 1904 of the interposer wafer 1902 can be coupled to the second side 1912 of the interposer wafer 1908 by a set of bump-bonds 1920. Although FIG. 19 depicts the set of bump-bonds 1920 as including five bump-bonds, this is a mere non-limiting example for ease of illustration. In various aspects, the set of bump-bonds 1920 can include any suitable number of bump-bonds as desired (e.g., at least one bump-bond). In various instances, as shown, each of the set of bump-bonds 1920 can be comprised of a solder bump that is sandwiched between two under-bump metallizations, just like each of the set of bump-bonds 114. Although FIG. 19 depicts each of the set of bump-bonds 1920 as having the same shapes, dimensions, and/or compositions as each of the set of bump-bonds 114, this is a mere non-limiting example for ease of illustration. In various cases, any of the set of bump-bonds 1920 can have the same and/or different shapes, dimensions, and/or compositions as any of the set of bump-bonds 114. Indeed, in some cases, the set of bump-bonds 114 can be physically smaller than each of the set of bump-bonds 1920, which can be beneficial for saving space. In various instances, the set of bump-bonds 1920 can be manufactured by any suitable microfabrication and/or nanofabrication techniques as desired (e.g., photolithography, deposition, etching, double-angle evaporation, electroplating, injection molding). In various cases, the set of bump-bonds 1920 can be manufactured at any suitable locations and/or positions between the first side 1904 of the interposer wafer 1902 and the second side 1912 of the interposer wafer 1908 (e.g., the locations/positions of the set of bump-bonds 1920 between the first side 1904 and the second side 1912 that are depicted in FIG. 19 are mere non-limiting examples for purposes of illustration).

Although not explicitly shown in FIG. 19, any other suitable superconducting wiring, non-superconductive wiring, coaxial cabling, superconducting circuit structures, non-superconducting circuit structures, and/or dielectric materials/structures can be manufactured on the first side 1910 of the interposer wafer 1908 as desired, can be manufactured on the second side 1912 of the interposer wafer 1908 as desired, can be manufactured on the first side 1904 of the interposer wafer 1902 as desired, can be manufactured on the second side 1906 of the interposer wafer 1902 as desired, can be manufactured between the first side 1910 and the second side 1912 of the interposer wafer 1908 as desired, and/or can be manufactured between the first side 1904 and the second side 1906 of the interposer wafer 1902 as desired. Such other wiring and/or structures are omitted from FIG. 19 for ease of illustration and/or for purposes of visual clarity.

In various aspects, as shown, the high-density flip-chip co-package 100 can be bump-bonded to the interposer wafer 1908. More specifically, a set of bump-bonds 1922 can couple the first side 1910 of the interposer wafer 1908 to the first side 110 of the silicon wafer 104. Although FIG. 19 depicts the set of bump-bonds 1922 as including two bump-bonds, this is a mere non-limiting example for ease of illustration. In various aspects, the set of bump-bonds 1922 can include any suitable number of bump-bonds as desired (e.g., at least one bump-bond). In various instances, as shown, each of the set of bump-bonds 1922 can be comprised of a solder bump that is sandwiched between two under-bump metallizations, just like each of the set of bump-bonds 114, and/or just like each of the set of bump-bonds 1920. Although FIG. 19 depicts each of the set of bump-bonds 1922 as having the same shapes, dimensions, and/or compositions as each of the set of bump-bonds 114 and/or as each of the set of bump-bonds 1920, this is a mere non-limiting example for ease of illustration. In various cases, any of the set of bump-bonds 1922 can have the same and/or different shapes, dimensions, and/or compositions as any of the set of bump-bonds 114 and/or as any of the set of bump-bonds 1920. Indeed, in some cases, the set of bump-bonds 114 can be physically smaller than each of the set of bump-bonds 1920 and/or than each of the set of bump-bonds 1922, which can be beneficial for saving space. In various aspects, the set of bump-bonds 1922 can be manufactured by any suitable microfabrication and/or nanofabrication techniques as desired (e.g., photolithography, deposition, etching, double-angle evaporation, electroplating). In various instances, the set of bump-bonds 1922 can be manufactured at any suitable locations and/or positions between the first side 110 of the silicon wafer 104 and the first side 1910 of the interposer wafer 1908 (e.g., the locations/positions of the set of bump-bonds 1922 between the first side 110 and the first side 1910 that are depicted in FIG. 19 are mere non-limiting examples for purposes of illustration).

In various instances, an underfill 1924 can be injected in between the first side 1904 of the interposer wafer 1902 and the second side 1912 of the interposer wafer 1908, such that the underfill 1924 surrounds the set of bump-bonds 1920, surrounds/covers the set of parametric Josephson devices 1914, and/or separates the interposer wafer 1902 from the interposer wafer 1908. In various aspects, the underfill 1924 can be any suitable thermoset epoxy (e.g., can include any suitable epoxy polymer in combination with any suitable amount of any suitable filler). In some cases, the underfill 1924 can have the same and/or different composition as the underfill 126. In some instances, the composition of the underfill 1924 can be controlled so that a coefficient-of-thermal-expansion of the underfill 1924 matches that of the interposer wafer 1902 and/or of the interposer wafer 1908 (e.g., the interposer wafer 1902 and the interposer wafer 1908 can have the same coefficient-of-thermal-expansion, since they can both be made of silicon). In any case, the underfill 1924 can function and/or serve as a barrier layer that prevents and/or reduces mechanical stresses and/or chemical corrosion which the set of parametric Josephson devices 1914 would otherwise experience during subsequent fabrication processing.

Next, consider the cross-sectional diagram 2000 of FIG. 20. In various embodiments, as shown, the interposer wafer 1908 can be bump-bonded to the organic substrate 1802 by the set of bump-bonds 1804. Although FIG. 20 depicts each of the set of bump-bonds 1804 as having the same shapes, dimensions, and/or compositions as each of the set of bump-bonds 114, as each of the set of bump-bonds 1920, and/or as each of the set of bump-bonds 1922, this is a mere non-limiting example for ease of illustration. In various cases, any of the set of bump-bonds 1804 can have the same and/or different shapes, dimensions, and/or compositions as any of the set of bump-bonds 114, as any of the set of bump-bonds 1920, and/or as any of the set of bump-bonds 1922.

Although FIGS. 19-20 depict a single instance of the high-density flip-chip co-package 100 being bump-bonded to the interposer wafer 1908, this is a mere non-limiting example for ease of illustration. In various aspects, any suitable number of high-density flip-chip co-packages (e.g., two or more instances and/or copies of the high-density flip-chip co-package 100) can be bump-bonded to the first side 1910 of the interposer wafer 1908.

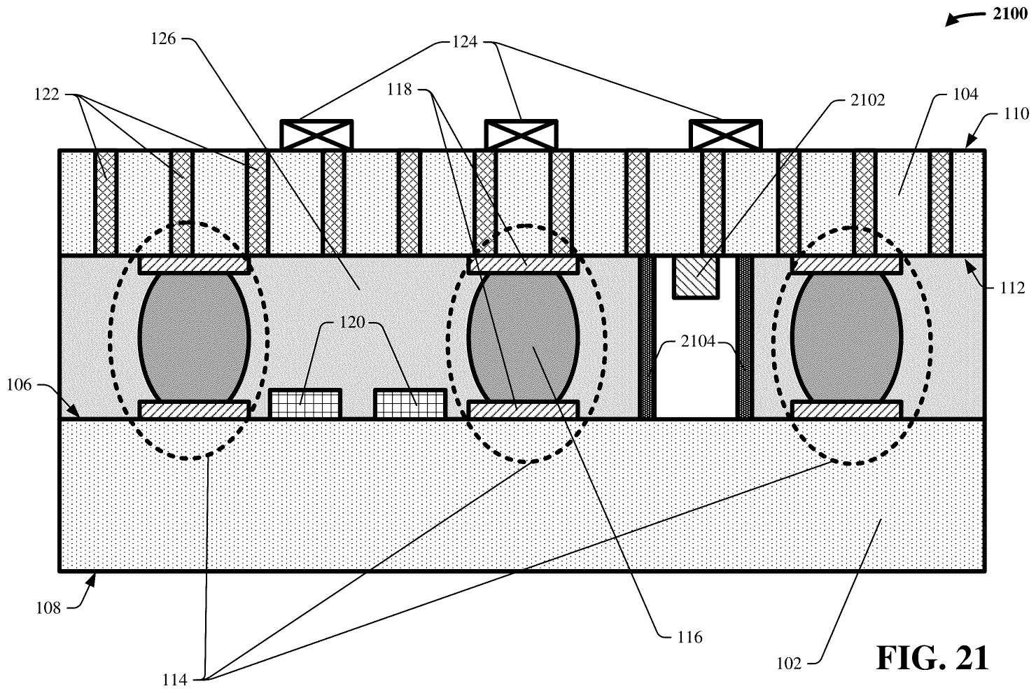

FIG. 21 illustrates a cross-sectional diagram of an example, non-limiting high-density flip-chip co-package for superconducting qubits and parametric Josephson devices including a trimmable air bridge for frequency tuning in accordance with one or more embodiments described herein. More specifically, FIG. 21 depicts a high-density flip-chip co-package 2100 that can be considered as an alternative to the high-density flip-chip co-package 100.

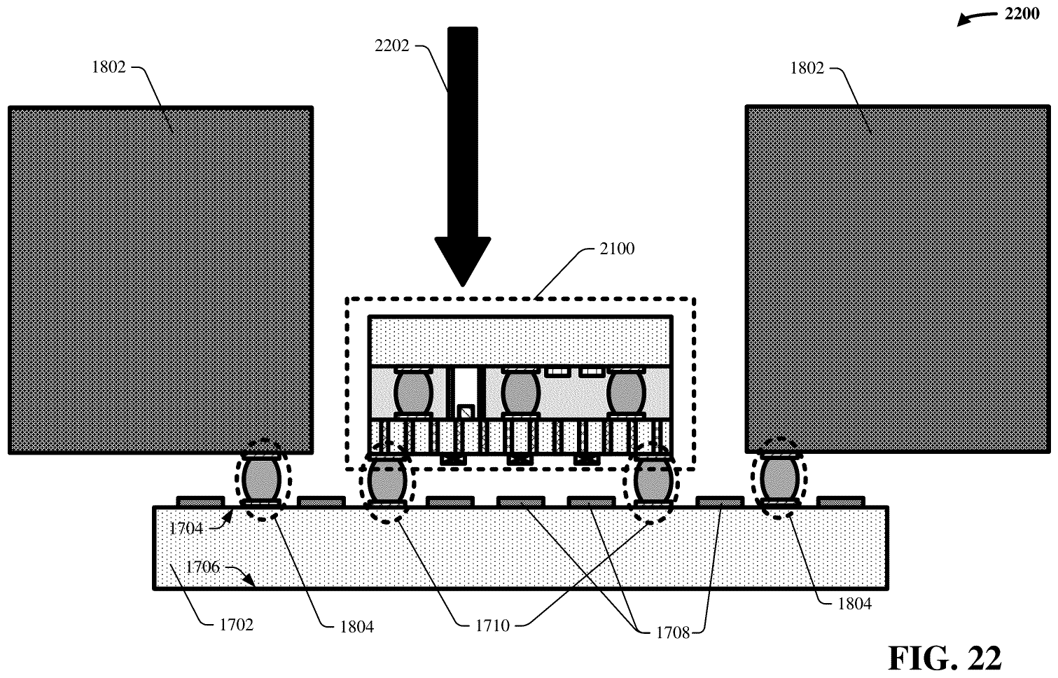

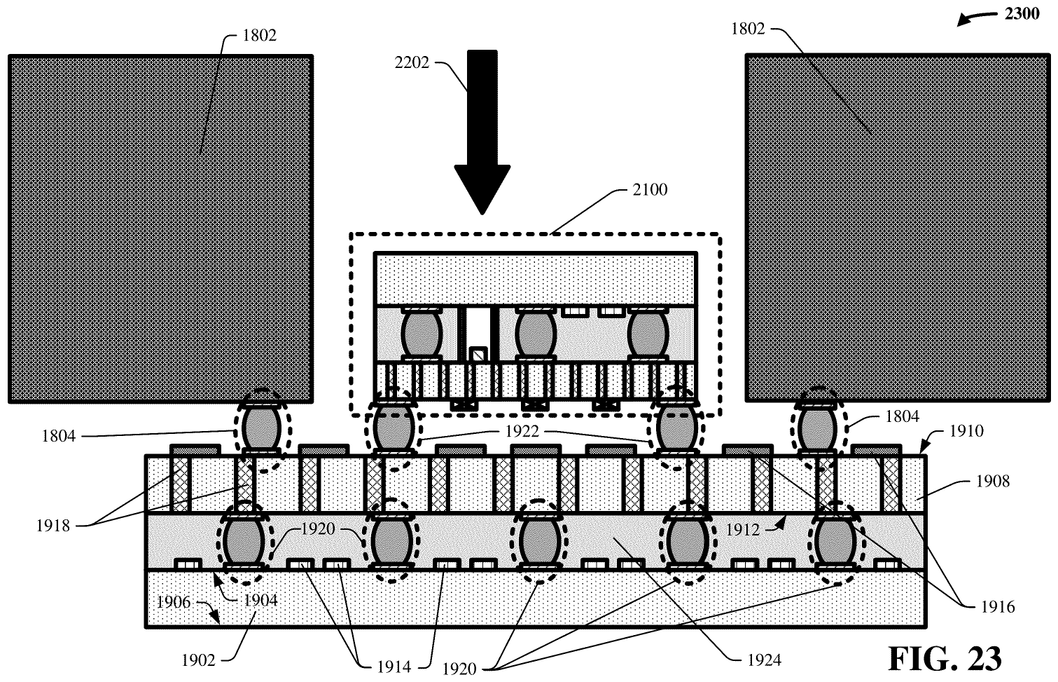

In various embodiments, the silicon wafer 102, the silicon wafer 104, the set of bump-bonds 114, the set of parametric Josephson devices 120, the set of through-substrate vias 122, the set of superconducting qubits 124, and/or the underfill 126 can be as described above. In various aspects, however, a segmented electrode 2102 can be located on the second side 112 of the silicon wafer 104, and a hollow photoresist column/pillar 2104 can prevent the underfill 126 from covering the segmented electrode 2102. In particular, the segmented electrode 2102 can include one or more air bridges that are laser-trimmable to tune an operational frequency of one or more of the set of superconducting qubits 124. Moreover, the hollow photoresist column/pillar 2104 can circumscribe the segmented electrode 2102 and/or can stretch from the first side 106 of the silicon wafer 102 to the second side 112 of the silicon wafer 104. In various cases, the segmented electrode 2102 and/or the hollow photoresist column/pillar 2104 can be fabricated by any suitable microfabrication and/or nanofabrication techniques (e.g., photolithography, deposition, etching, double-angle evaporation, electroplating) prior to injection of the underfill 126. Accordingly, when the underfill 126 is injected in between the silicon wafer 102 and the silicon wafer 104, the hollow photoresist column/pillar 2104 can prevent the underfill 126 from covering the segmented electrode 2102. Accordingly, the segmented electrode 2102 can be trimmed by any suitable laser that can pass through the silicon wafer 102 (e.g., the wavelength of the laser can be controllably set to any suitable value for which the silicon wafer 102 behaves as transparent). Such laser trimming of the air bridges of the segmented electrode 2102, which can commensurately tune one or more operational frequencies of the set of superconducting qubits 124, is more fully shown in FIGS. 22-23.

Although FIG. 21 depicts a single segmented electrode 2102 as being located on the second side 112 of the silicon wafer 104, this is a mere non-limiting example for ease of illustration. In various cases, any suitable number of segmented electrodes can be fabricated on the second side 112 (and/or on the first side 110) of the silicon wafer 104. Likewise, although FIG. 21 depicts a single hollow photoresist column/pillar 2104, this is a mere non-limiting example of ease of illustration. In various aspects, any suitable number of hollow photoresist columns/pillars can be fabricated between the silicon wafer 104 and/or the silicon wafer 102.

FIGS. 22-23 illustrate example, non-limiting cross-sectional diagrams 2200 and 2300 showing how a high-density flip-chip co-package for superconducting qubits and parametric Josephson devices including a trimmable air bridge for frequency tuning can be coupled to interposers and/or organic substrates in accordance with one or more embodiments described herein.

First, consider the cross-sectional diagram 2200 of FIG. 22. In various embodiments, as shown, the interposer wafer 1702, the set of resonators 1708, the set of bump-bonds 1710, the organic substrate 1802, and/or the set of bump-bonds 1804 can be as described above. In various aspects, however, the high-density flip-chip co-package 2100, instead of the high-density flip-chip co-package 100, can be coupled by the set of bump-bonds 1710 to the interposer wafer 1702. In such case, as shown, the second side 108 of the silicon wafer 102 can be considered as facing upwards. Accordingly, in various instances, a laser 2202 can be directed downward toward the second side 108 of the silicon wafer 102. In various cases, the wavelength of the laser 2202 can be controllably set so that the laser 2202 can transparently pass through the silicon wafer 102. Accordingly, the laser 2202 can hit, melt, severe, and/or otherwise trim one or more air bridges of the segmented electrode 2102, thereby facilitating tuning of the set of superconducting qubits 124.

Next, consider the cross-sectional diagram 2300 of FIG. 23. In various embodiments, as shown, the interposer wafer 1902, the interposer wafer 1908, the set of resonators 1916, the set of parametric Josephson devices 1914, the set of through-substrate vias 1918, the set of bump-bonds 1920, the set of bump-bonds 1922, the organic substrate 1802, and/or the set of bump-bonds 1804 can be as described above. In various aspects, however, the high-density flip-chip co-package 2100, instead of the high-density flip-chip co-package 100, can be coupled by the set of bump-bonds 1922 to the interposer wafer 1908. In such case, as shown, the second side 108 of the silicon wafer 102 can be considered as facing upwards. Accordingly, in various instances, the laser 2202 can be directed downward toward the second side 108 of the silicon wafer 102. As mentioned above, the wavelength of the laser 2202 can be controllably set so that the laser 2202 can transparently pass through the silicon wafer 102. Accordingly, the laser 2202 can hit one or more air bridges of the segmented electrode 2102, thereby facilitating tuning of the set of superconducting qubits 124.

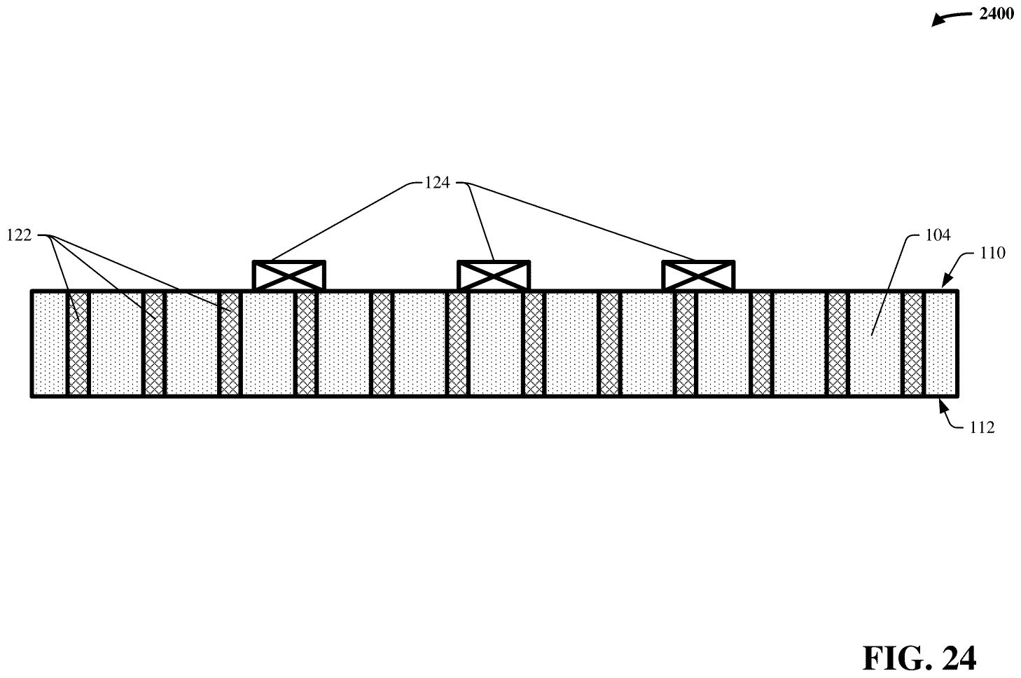

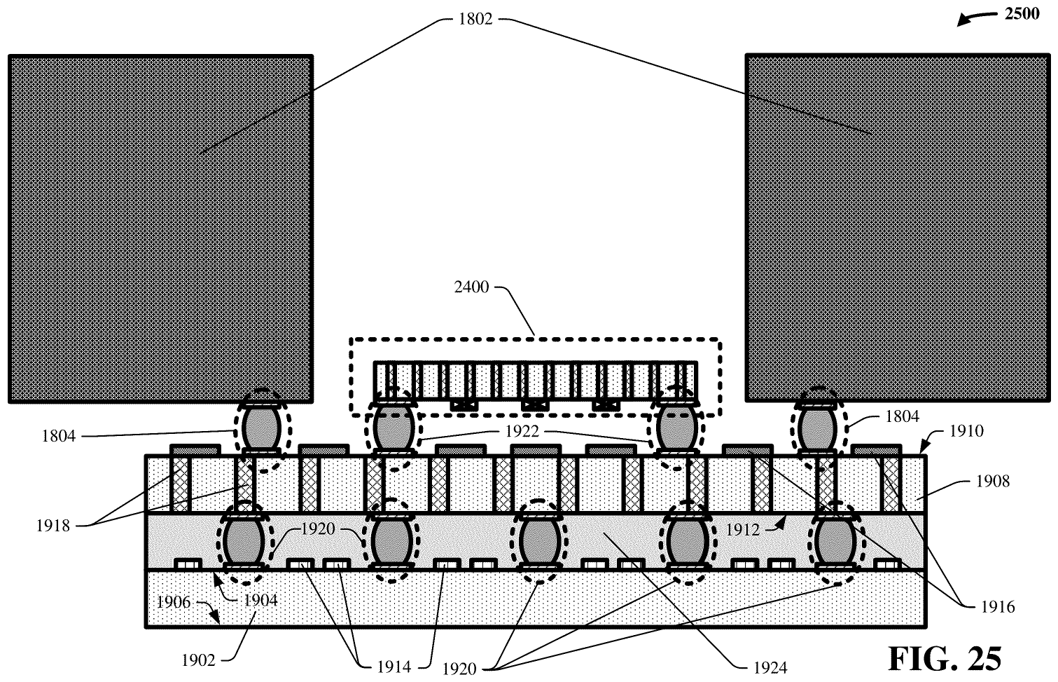

FIGS. 24-25 illustrate cross-sectional diagrams of another example, non-limiting high-density flip-chip co-package for superconducting qubits and parametric Josephson devices coupled to interposers and/or organic substrates in accordance with one or more embodiments described herein.

First, consider FIG. 24. As shown, there can be a structure 2400 that includes the silicon wafer 104, the set of through-substrate vias 122, and/or the set of superconducting qubits 124. As can be seen, the structure 2400 can be considered as being equivalent to the high-density flip-chip co-package 100, less the silicon wafer 102, less the set of parametric Josephson devices 120, less the set of bump-bonds 114, and/or less the underfill 126.

Next, consider the block-diagram 2500 of FIG. 25. In various embodiments, as shown, the interposer wafer 1902, the interposer wafer 1908, the set of resonators 1916, the set of parametric Josephson devices 1914, the set of through-substrate vias 1918, the set of bump-bonds 1920, the set of bump-bonds 1922, the organic substrate 1802, and/or the set of bump-bonds 1804 can be as described above. In various aspects, however, the structure 2400, instead of the high-density flip-chip co-package 100, can be coupled by the set of bump-bonds 1922 to the interposer wafer 1908. Just as mentioned above, the underfill 1924 that separates the interposer wafer 1902 from the interposer wafer 1908 can be considered as a protective shield/barrier that eliminates and/or ameliorates excessive mechanical/chemical damage that the set of parametric Josephson devices 1914 would otherwise experience during subsequent fabrication processing (e.g., during bump-bonding of the structure 2400 to the interposer wafer 1908).

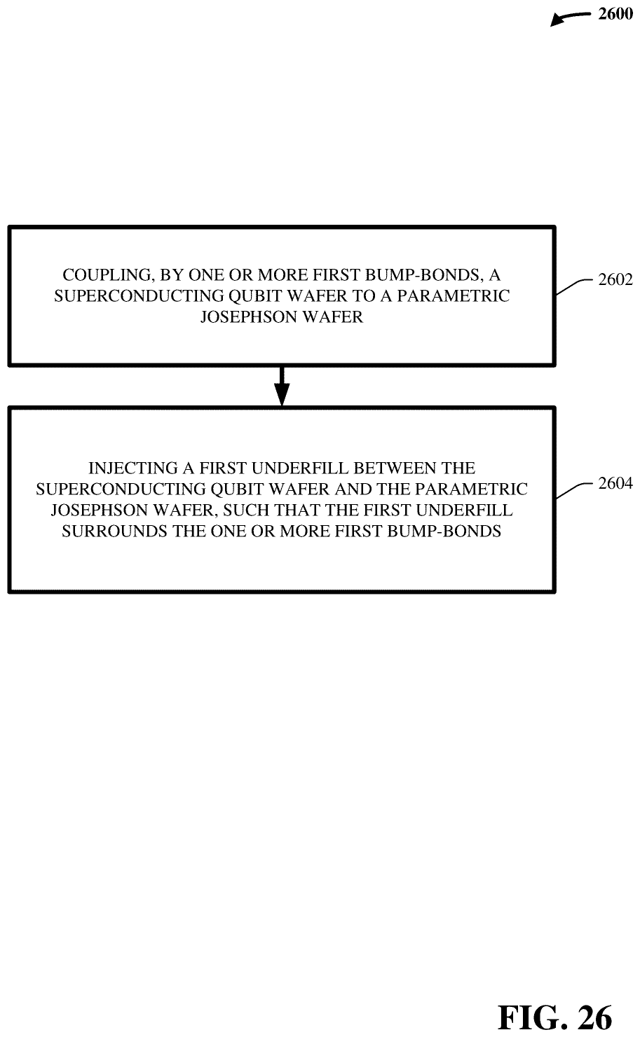

FIG. 26 illustrates a block diagram of an example, non-limiting method 2600 for facilitating high-density flip-chip co-packages for superconducting qubits and parametric Josephson devices in accordance with one or more embodiments described herein.

In various embodiments, act 2602 can include coupling, by one or more first bump-bonds (e.g., 114), a superconducting qubit wafer (e.g., 104) to a parametric Josephson wafer (e.g., 102).

In various aspects, act 2604 can include injecting a first underfill (e.g., 126) between the superconducting qubit wafer and the parametric Josephson wafer, such that the first underfill surrounds the one or more bump-bonds and/or surrounds/covers one or more parametric Josephson devices of the parametric Josephson wafer.

Although not explicitly recited in FIG. 26, at least one first parametric Josephson device (e.g., 120) can be located on a first side (e.g., 106) of the parametric Josephson wafer, and/or at least one superconducting qubit (e.g., 124) comprising a Josephson junction can be located on a first side (e.g., 110) of the superconducting qubit wafer. In various cases, the superconducting qubit wafer can include at least one first through-substrate via (e.g., 122) electrically connecting the first side of the superconducting qubit wafer to a second side (e.g., 112) of the superconducting qubit wafer. In various aspects, the one or more first bump-bonds can couple the first side of the parametric Josephson wafer to the second side of the superconducting qubit wafer.

Although not explicitly recited in FIG. 26, the method 2600 can further comprise: coupling, by one or more second bump-bonds (e.g., 1710), an interposer wafer (e.g., 1702) to the superconducting qubit wafer, wherein at least one resonator (e.g., 1708) can be located on a first side (e.g., 1704) of the interposer wafer, and wherein the one or more second bump-bonds can couple the first side of the interposer wafer to the first side of the superconducting qubit wafer. In various cases, the first side of the interposer wafer can be bump-bonded (e.g., by 1804) to an organic substrate (e.g., 1802), where the organic substrate can be a printed circuit board, a flexible printed circuit board, and/or a laminate.

Although not explicitly recited in FIG. 26, the method 2600 can further comprise: coupling, by one or more second bump-bonds (e.g., 1920), a first interposer wafer (e.g., 1902) to a second interposer wafer (e.g., 1908); and injecting a second underfill (e.g., 1924) between the first interposer wafer and the second interposer wafer, such that the second underfill surrounds the one or more second bump-bonds. In various aspects, at least one second parametric Josephson device (e.g., 1914) can be located on a first side (e.g., 1904) of the first interposer wafer, and/or at least one resonator (e.g., 1916) can be located on a first side (e.g., 1910) of the second interposer wafer. In various instances, at least one second through-substrate via (e.g., 1918) can electrically connect the first side of the second interposer wafer to a second side (e.g., 1912) of the second interposer wafer, and the one or more second bump-bonds can couple the first side of the first interposer wafer to the second side of the second interposer wafer. In various cases, the first side of the superconducting qubit wafer can be bump-bonded, by one or more third bump-bonds (e.g., 1922), to the first side of the second interposer wafer. In various instances, the first side of the second interposer wafer can be bump-bonded (e.g., by 1804) to an organic substrate (e.g., 1802), where the organic substrate can be a printed circuit board, a flexible printed circuit board, and/or a laminate.

Although not explicitly recited in FIG. 26, at least one segmented electrode (e.g., 2102) that corresponds to the at least one superconducting qubit can be located on the second side of the superconducting qubit wafer, wherein the at least one segmented electrode can include at least one air bridge that is trimmable to tune an operational frequency of the at least one superconducting qubit. In various cases, at least one hollow photoresist column (e.g., 2104) can stretch from the first side of the parametric Josephson wafer to the second side of the superconducting qubit wafer and can prevent the first underfill from covering the at least one air bridge.

Although not explicitly recited in FIG. 26, the method 2600 can further comprise: coupling, by one or more second bump-bonds (e.g., another instance of 114), another superconducting qubit wafer (e.g., another instance of 104) to another parametric Josephson wafer (e.g., another instance of 102); injecting a second underfill (e.g., another instance of 126) between the another superconducting qubit wafer and the another parametric Josephson wafer, such that the second underfill surrounds the one or more second bump-bonds and/or surrounds one or more second parametric Josephson devices of the another parametric Josephson wafer; and coupling, by one or more third bump-bonds (e.g., another instance of 1710 or another instance of 1922), both the superconducting qubit wafer and the another superconducting qubit wafer to an interposer wafer (e.g., 1702 and/or 1908), wherein the interposer wafer can be bump-bonded to an organic substrate (e.g., 1802).

Various embodiments described herein can provide a flip-chip package, where such flip-chip package can comprise: a first wafer (e.g., 102) bump-bonded to a second wafer (e.g., 104), wherein the first wafer includes one or more parametric Josephson devices (e.g., 120), and wherein the second wafer includes one or more superconducting qubits (e.g., 124); and an underfill (e.g., 126) that separates the first wafer from the second wafer. In various cases, the underfill can protect and/or safeguard the one or more parametric Josephson devices from mechanical and/or chemical damage that would otherwise result during subsequent fabrication and/or processing of the one or more superconducting qubits.

In various aspects, such flip-chip package can further comprise: an interposer (e.g., 1702; or collectively 1902 and 1908) that is bump-bonded to both the second wafer and an organic substrate (e.g., 1802). In various instances, the interposer can include one or more resonators (e.g., 1708; or 1916). In various cases, the interposer can include a first interposer wafer (e.g., 1902) bump-bonded (e.g., by 1920) to a second interposer wafer (e.g., 1908), wherein the first interposer wafer can include one or more other parametric Josephson devices (e.g., 1914), wherein the second interposer wafer can include one or more resonators (e.g., 1916), wherein another underfill (e.g., 1924) can separate the first interposer wafer from the second interposer wafer, wherein the second wafer can be bump-bonded (e.g., by 1922) to the second interposer wafer, and/or wherein the another underfill can protect/safeguard the one or more other parametric Josephson devices from mechanical and/or chemical damage.

Accordingly, various embodiments described herein can be considered as a high-density flip-chip co-package that can implement both superconducting qubits and parametric Josephson devices, with no and/or negligible amounts of mechanical/chemical degradation afflicting the parametric Josephson devices, and without the excessive consumption of space that afflicts separate-packaging techniques. Such a high-density flip-chip co-package certainly constitutes a concrete and tangible technical improvement in the field of qubits.

The herein disclosure describes non-limiting examples of various embodiments of the subject innovation. For ease of description and/or explanation, various portions of the herein disclosure utilize the term “each” when discussing various embodiments of the subject innovation. Such usages of the term “each” are non-limiting examples. In other words, when the herein disclosure provides a description that is applied to “each” of some particular object and/or component, it should be understood that this is a non-limiting example of various embodiments of the subject innovation, and it should be further understood that, in various other embodiments of the subject innovation, it can be the case that such description applies to fewer than “each” of that particular object and/or component.

The flowcharts in the Figures illustrate the architecture, functionality, and operation of possible implementations of systems, methods, and computer program products according to various embodiments described herein. In this regard, each block in the flowchart can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the flowchart illustrations, and combinations of blocks in the flowchart illustrations, can be implemented by special purpose hardware-based systems that perform the specified functions or acts or carry out combinations of special purpose hardware and computer instructions.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

What has been described above include mere examples of systems and computer-implemented methods. It is, of course, not possible to describe every conceivable combination of components or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a superconducting qubit wafer coupled, by one or more first bump-bonds, to a parametric Josephson wafer; and
a first underfill that surrounds the one or more first bump-bonds.

2. The device of claim 1, wherein the first underfill is a composite material comprising an epoxy polymer and a filler, wherein the filler is at least one material selected from the group consisting of silicon dioxide, titanium dioxide, carbon nanotubes, carbon black, and graphene.

3. The device of claim 1, wherein at least one first parametric Josephson device is located on a first side of the parametric Josephson wafer, wherein at least one superconducting qubit is located on a first side of the superconducting qubit wafer, wherein the superconducting qubit wafer includes at least one first through-substrate via electrically connecting the first side of the superconducting qubit wafer to a second side of the superconducting qubit wafer, and wherein the one or more first bump-bonds couple the first side of the parametric Josephson wafer to the second side of the superconducting qubit wafer.

4. The device of claim 3, wherein the at least one first parametric Josephson device includes a Josephson parametric amplifier, a Josephson travelling-wave parametric amplifier, a Josephson directional amplifier, a Josephson parametric converter, a Josephson circulator, or a Josephson isolator.

5. The device of claim 3, further comprising:
an interposer wafer bump-bonded, by one or more second bump-bonds, to the superconducting qubit wafer, wherein at least one resonator is located on a first side of the interposer wafer.

6. The device of claim 5, wherein the one or more second bump-bonds couple the first side of the interposer wafer to the first side of the superconducting qubit wafer.

7. The device of claim 6, wherein the first side of the interposer wafer is bump-bonded to an organic substrate, and wherein the organic substrate is selected from the group consisting of a printed circuit board, a flexible printed circuit board, and a laminate.

8. The device of claim 3, further comprising:
a first interposer wafer bump-bonded, by one or more second bump-bonds, to a second interposer wafer; and
a second underfill that surrounds the one or more second bump-bonds.

9. The device of claim 8, wherein at least one second parametric Josephson device is located on a first side of the first interposer wafer, and wherein at least one resonator is located on a first side of the second interposer wafer.

10. The device of claim 9, wherein at least one second through-substrate via electrically connects the first side of the second interposer wafer to a second side of the second interposer wafer, and wherein the one or more second bump-bonds couple the first side of the first interposer wafer to the second side of the second interposer wafer.

11. The device of claim 10, wherein the first side of the superconducting qubit wafer is bump-bonded, by one or more third bump-bonds, to the first side of the second interposer wafer, wherein the first side of the second interposer wafer is bump-bonded to an organic substrate, and wherein the organic substrate is selected from the group consisting of a printed circuit board, a flexible printed circuit board, and a laminate.

12. The device of claim 3, wherein at least one segmented electrode that corresponds to the at least one superconducting qubit is located on the second side of the superconducting qubit wafer, wherein the at least one segmented electrode includes at least one air bridge that is trimmable to tune an operational frequency of the at least one superconducting qubit, and wherein at least one hollow photoresist column stretches from the first side of the parametric Josephson wafer to the second side of the superconducting qubit wafer and prevents the underfill from covering the at least one air bridge.

13. The device of claim 1, further comprising:
an interposer wafer;
another superconducting qubit wafer coupled, by one or more second bump-bonds, to another parametric Josephson wafer; and
a second underfill that surrounds the one or more second bump-bonds and that surrounds one or more second parametric Josephson devices of the another parametric Josephson wafer, wherein both the superconducting qubit wafer and the another superconducting qubit wafer are bump-bonded, by one or more third bump-bonds, to the interposer wafer, and wherein the interposer wafer is bump-bonded to an organic substrate.

14. A method, comprising:
coupling, by one or more first bump-bonds, a superconducting qubit wafer to a parametric Josephson wafer; and
injecting a first underfill between the superconducting qubit wafer and the parametric Josephson wafer, such that the first underfill surrounds the one or more first bump-bonds.

15. The method of claim 14, wherein at least one first parametric Josephson device is located on a first side of the parametric Josephson wafer, wherein at least one superconducting qubit is located on a first side of the superconducting qubit wafer, wherein the superconducting qubit wafer includes at least one first through-substrate via electrically connecting the first side of the superconducting qubit wafer to a second side of the superconducting qubit wafer, and wherein the one or more first bump-bonds couple the first side of the parametric Josephson wafer to the second side of the superconducting qubit wafer.

16. The method of claim 15, further comprising:
coupling, by one or more second bump-bonds, a first interposer wafer to a second interposer wafer; and
injecting a second underfill between the first interposer wafer and the second interposer wafer, such that the second underfill surrounds the one or more second bump-bonds.

17. The method of claim 16, wherein at least one second parametric Josephson device is located on a first side of the first interposer wafer, and wherein at least one resonator is located on a first side of the second interposer wafer.

18. The method of claim 17, wherein at least one second through-substrate via electrically connects the first side of the second interposer wafer to a second side of the second interposer wafer, wherein the one or more second bump-bonds couple the first side of the first interposer wafer to the second side of the second interposer wafer, wherein the first side of the superconducting qubit wafer is bump-bonded, by one or more third bump-bonds, to the first side of the second interposer wafer, wherein the first side of the second interposer wafer is bump-bonded to an organic substrate, and wherein the organic substrate is selected from the group consisting of a printed circuit board, a flexible printed circuit board, and a laminate.

19. The method of claim 15, wherein at least one segmented electrode that corresponds to the at least one superconducting qubit is located on the second side of the superconducting qubit wafer, wherein the at least one segmented electrode includes at least one air bridge that is trimmable to tune an operational frequency of the at least one superconducting qubit, and wherein at least one hollow photoresist column stretches from the first side of the parametric Josephson wafer to the second side of the superconducting qubit wafer and prevents the first underfill from covering the at least one air bridge.

20. The method of claim 14, further comprising:
coupling, by one or more second bump-bonds, another superconducting qubit wafer to another parametric Josephson wafer;
injecting a second underfill between the another superconducting qubit wafer and the another parametric Josephson wafer, such that the second underfill surrounds the one or more second bump-bonds and surrounds one or more second parametric Josephson devices of the another parametric Josephson wafer; and
coupling, by one or more third bump-bonds, both the superconducting qubit wafer and the another superconducting qubit wafer to an interposer wafer, wherein the interposer wafer is bump-bonded to an organic substrate.

21. A flip-chip package, comprising:
a first wafer bump-bonded to a second wafer, wherein the first wafer includes one or more parametric Josephson devices, and wherein the second wafer includes one or more superconducting qubits; and
an underfill that separates the first wafer from the second wafer, wherein the one or more parametric Josephson devices are located between the underfill and the first wafer.
